(19) United States
(12) Patent Application Publication
(10) Pub. No.: US 2026/0191033 A1
(43) Pub. Date: Jul. 2, 2026

(54) SEMICONDUCTOR DEVICE

(71) Applicant: ROHM CO., LTD., Kyoto-shi (JP)

(72) Inventors: Shunya MIKAMI, Kyoto-shi (JP); Yuto NISHIYAMA, Kyoto-shi (JP)

(21) Appl. No.: 19/544,765

(22) Filed: Feb. 19, 2026

Related U.S. Application Data
(63) Continuation of application No. PCT/JP2024/027771, filed on Aug. 2, 2024.

(30) Foreign Application Priority Data
Aug. 29, 2023 (JP) 2023-138669

(51) Int. Cl. H10W 70/40; H10W 72/00; H10W 74/10; H10W 90/00

(52) U.S. Cl. CPC H10W 70/429; H10W 70/417; H10W 72/884; H10W 74/114; H10W 90/736; H10W 90/756

(57) ABSTRACT

A semiconductor device includes a first lead, a semiconductor element, and a sealing resin. The first lead includes a pad portion and a first support part. The first support part has a first surface, a second surface, and a first end surface. The pad portion is exposed from the bottom surface of the sealing resin. The dimension of the sealing resin in the first direction from the bottom surface to the second surface is smaller than the dimension of the sealing resin in the first direction from the top surface to the first surface. The dimension of the second surface in the second direction is at least 50% of a dimension in the second direction of a region of the bottom surface that is adjacent, on one side in the second direction, to the pad portion and overlaps with the second surface as viewed in the first direction.

### TECHNICAL FIELD

The present disclosure relates to a semiconductor device.

### BACKGROUND ART

Resin package-type semiconductor devices, such as those disclosed in JP-A-2018-60908, are widely known. The semiconductor device disclosed in JP-A-2018-60908 includes a semiconductor element, a first lead electrically connected to the semiconductor element, a second lead on which the semiconductor element is mounted, and a sealing resin covering the semiconductor element. The first lead and the second lead protrude from the sealing resin.

The second lead of the semiconductor device disclosed in JP-A-2018-60908 has a second pad portion on which the semiconductor element is mounted. The second pad portion is provided with a protrusion. The protrusion protrudes in a direction orthogonal to the direction normal to the second pad surface facing the semiconductor element. In the configuration of the semiconductor device, the protrusion provided on the second pad portion may be utilized as a support member connecting the lead frame and the second lead. In the manufacturing of the semiconductor device in this case, it is necessary to cut the protrusion off from the lead frame after forming the sealing resin. At this time, load acts on the second lead including the protrusion, causing greater stress to concentrate on a portion of the sealing resin that is in contact with the second lead. This may cause cracks to form in the sealing resin.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2 as seen through a sealing resin.

FIG. 4 is a bottom view of the semiconductor device shown in FIG. 1.

FIG. 5 is a bottom view corresponding to FIG. 4 as seen through the sealing resin.

FIG. 6 is a front view of the semiconductor device shown in FIG. 1.

FIG. 7 is a right side view of the semiconductor device shown in FIG. 1.

FIG. 8 is a left side view of the semiconductor device shown in FIG. 1.

FIG. 9 is a sectional view taken along line IX-IX in FIG. 3.

FIG. 10 is a sectional view taken along line X-X in FIG. 3.

FIG. 11 is a sectional view taken along line XI-XI in FIG. 3.

FIG. 12 is a partially enlarged view of FIG. 3.

FIG. 13 is a partially enlarged view of FIG. 9.

FIG. 14 is a partially enlarged sectional view of a semiconductor device according to a first variation of the first embodiment of the present disclosure.

FIG. 15 is a partially enlarged sectional view of a semiconductor device according to a second variation of the first embodiment of the present disclosure.

FIG. 16 is a partially enlarged sectional view of a semiconductor device according to a third variation of the first embodiment of the present disclosure.

FIG. 17 is a sectional view illustrating a manufacturing process of the semiconductor device shown in FIG. 1.

FIG. 18 is a sectional view illustrating a manufacturing process of the semiconductor device shown in FIG. 1.

FIG. 19 is a sectional view illustrating a manufacturing process of the semiconductor device shown in FIG. 1.

FIG. 20 is a sectional view illustrating a manufacturing process of the semiconductor device shown in FIG. 1.

FIG. 21 is a sectional view illustrating a manufacturing process of the semiconductor device shown in FIG. 16.

FIG. 22 is a bottom view of a semiconductor device according to a second embodiment of the present disclosure as seen through the sealing resin.

FIG. 23 is a sectional view of the semiconductor device shown in FIG. 22, corresponding to FIG. 9.

FIG. 24 is a sectional view of the semiconductor device shown in FIG. 22, corresponding to FIG. 10 .

FIG. 25 is a partially enlarged view of FIG. 22.

FIG. 26 is a partially enlarged view of FIG. 23.

FIG. 27 is a partially enlarged sectional view of a semiconductor device according to a variation of the second embodiment of the present disclosure.

FIG. 28 is a sectional view illustrating a manufacturing process of the semiconductor device shown in FIG. 22.

FIG. 29 is a sectional view illustrating a manufacturing process of the semiconductor device shown in FIG. 22.

FIG. 30 is a sectional view illustrating a manufacturing process of the semiconductor device shown in FIG. 22.

FIG. 31 is a sectional view illustrating a manufacturing process of the semiconductor device shown in FIG. 27.

FIG. 32 is a sectional view illustrating a manufacturing process of the semiconductor device shown in FIG. 27.

### DETAILED DESCRIPTION OF EMBODIMENTS

The present disclosure will be described in detail with reference to the accompanying drawings.

### First Embodiment:

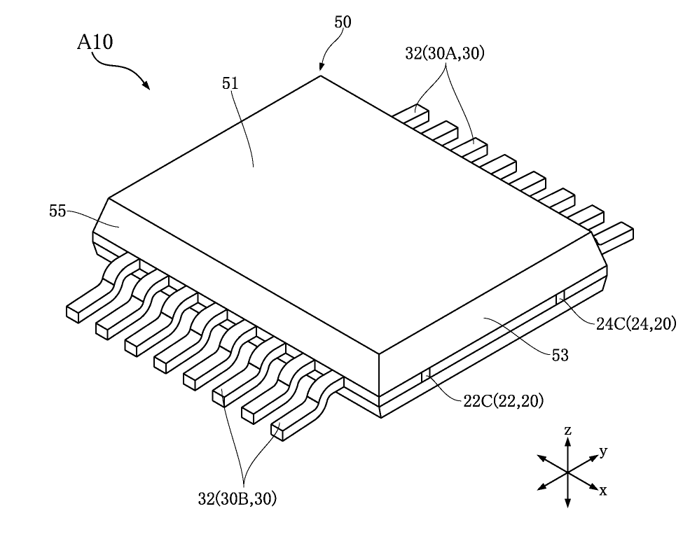

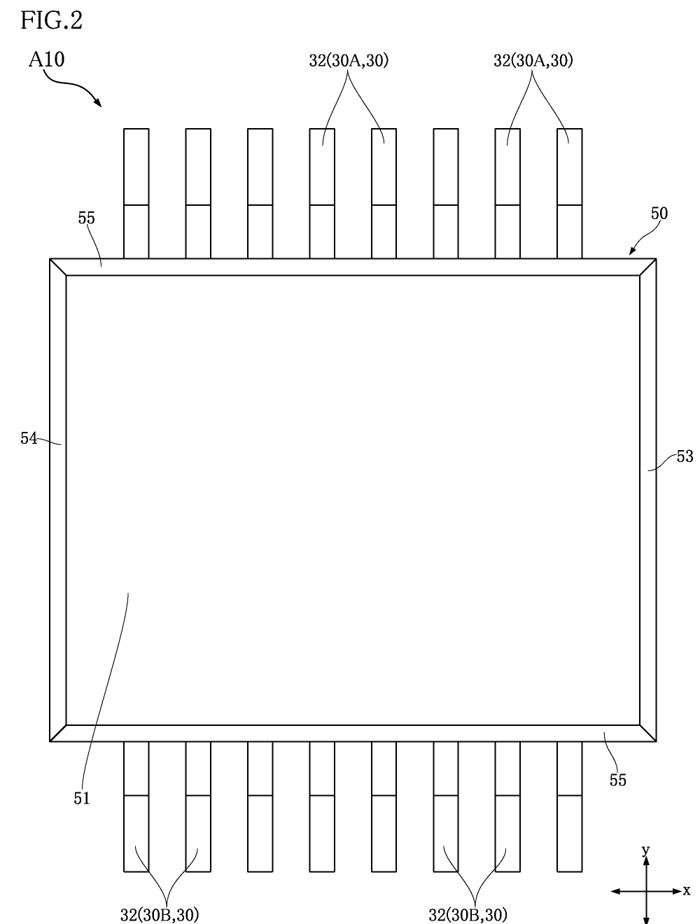

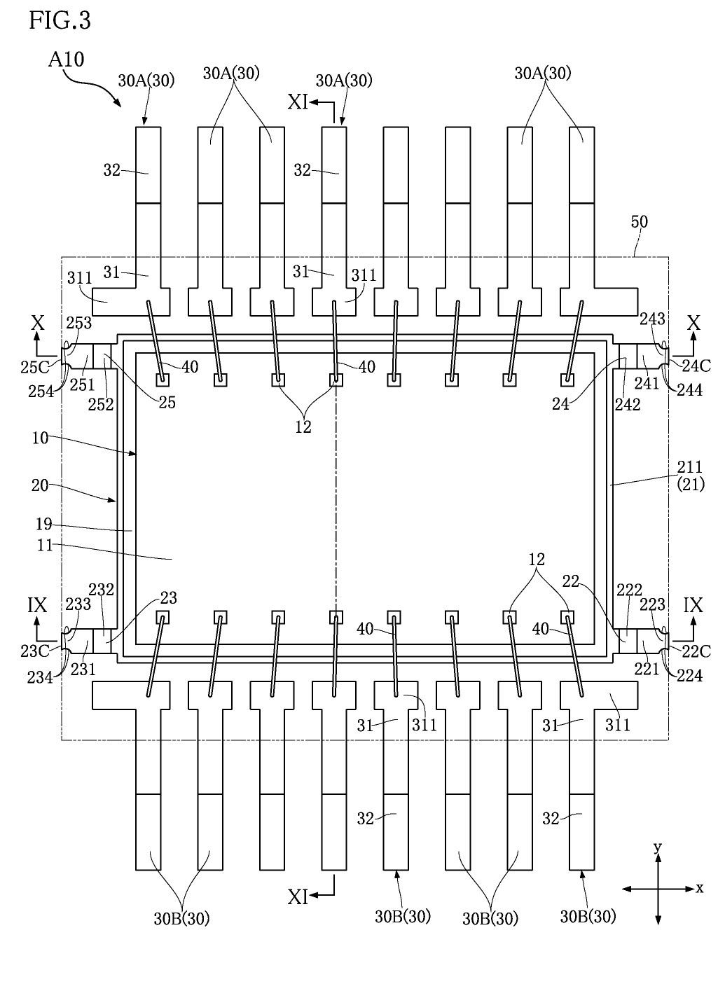

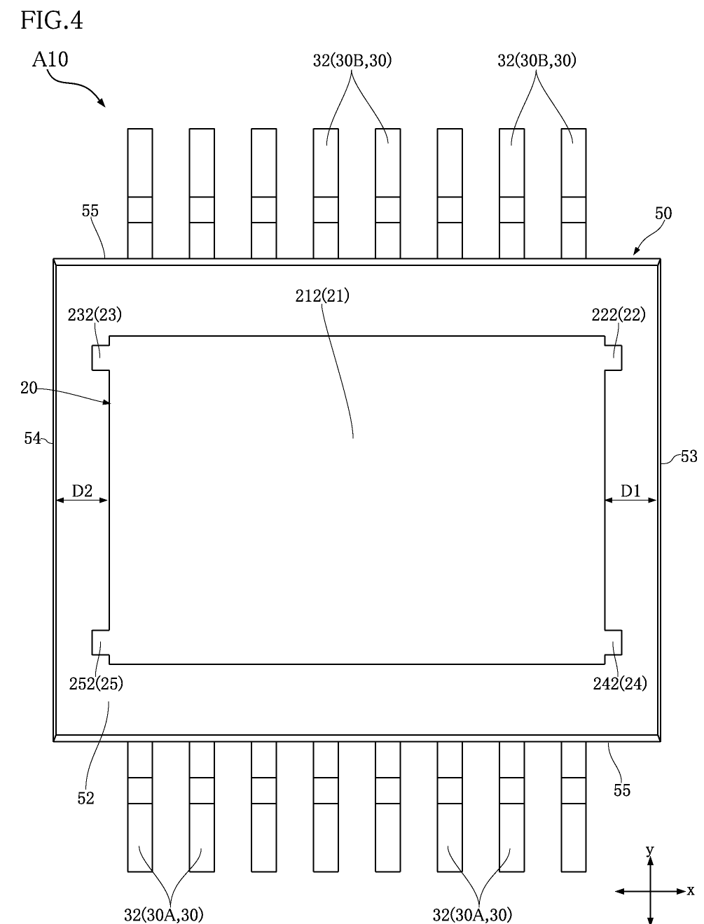

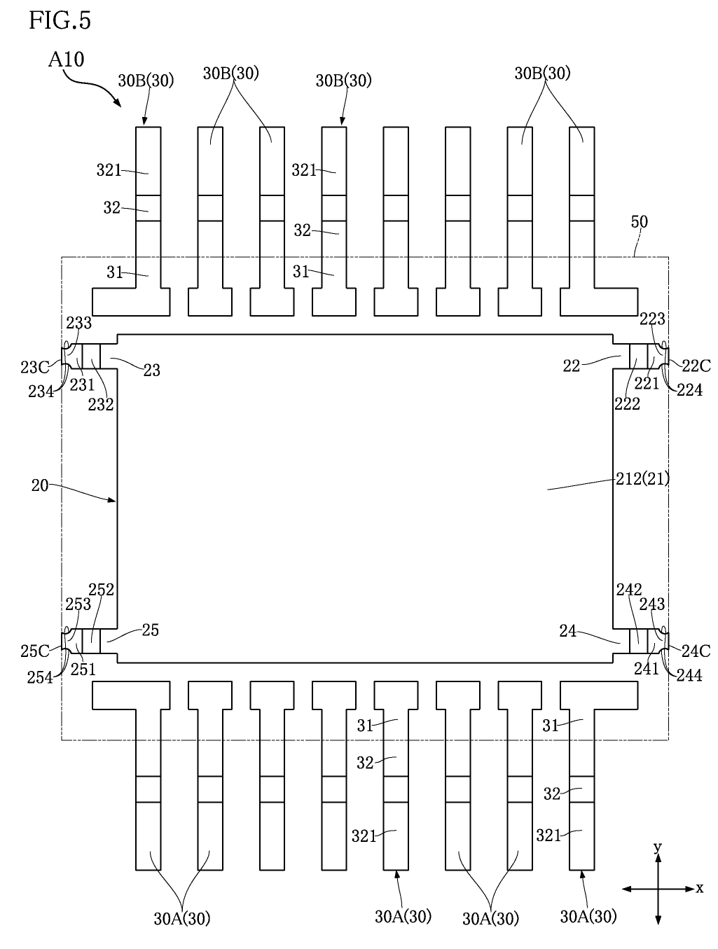

A semiconductor device A10 according to a first embodiment of the present disclosure will be described with reference to FIGS. 1 to 13. The semiconductor device A10 includes a semiconductor element 10, a first lead 20, a plurality of second leads 30, a plurality of wires 40, and a sealing resin 50. The semiconductor device A10 is of the SOP (Small Outline Package) type. However, the package type of the semiconductor device A10 is not limited to the SOP. FIGS. 3 and 5 show the sealing resin 50 as transparent for ease of understanding. In FIGS. 3 and 5, the outline of the sealing resin 50 is indicated by an imaginary line (two-dot line).

For convenience, in describing the semiconductor device A10, the direction normal to the mounting surface 211 of the pad portion 21, described later, is referred to as a first direction z. A direction orthogonal to the first direction z is referred to as a second direction x. The direction orthogonal to the first direction z and the second direction x is referred to as a third direction y.

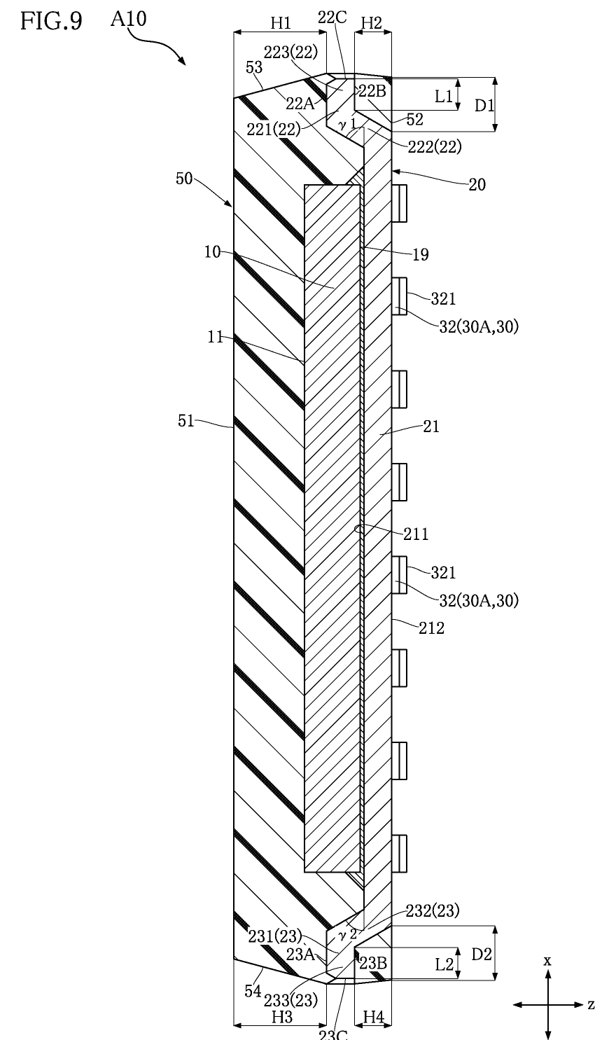

As shown in FIGS. 9 to 11, the sealing resin 50 covers the semiconductor element 10, a portion of the first lead 20, a portion of each of the second leads 30, and the wires 40. The sealing resin 50 is an insulator. The sealing resin 50 is made of a material including, for example, epoxy resin. As viewed in the first direction z, the sealing resin 50 is rectangular.

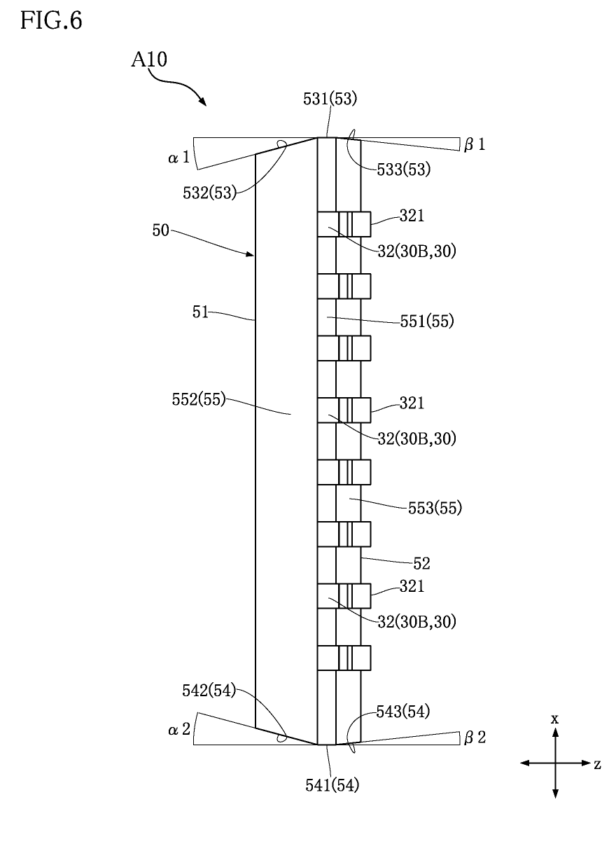

As shown in FIGS. 6 to 8, the sealing resin 50 has a top surface 51, a bottom surface 52, a first side surface 53, a second side surface 54, and two third side surfaces 55.

As shown in FIGS. 6 to 8, the top surface 51 faces one side in the first direction z. The top surface 51 faces the same side as the mounting surface 211 of the pad portion 21, described later, in the first direction z. The bottom surface 52 faces away from the top surface 51 in the first direction z.

As shown in FIG. 6, the first side surface 53 is connected to the top surface 51 and the bottom surface 52 and faces one side in the second direction x. The first side surface 53 includes a first region 531, a second region 532, and a third region 533. The first region 531 includes the first direction z as an in-plane direction. As viewed in the first direction z, the first region 531 is located outward relative to the top surface 51 and the bottom surface 52. The second region 532 is located between the first region 531 and the top surface 51 in the first direction z. The third region 533 is located opposite the second region 532 with respect to the first region 531. Each of the second region 532 and the third region 533 is inclined relative to the first region 531. The inclination angle α1 of the second region 532 relative to the first region 531 is greater than the inclination angle β1 of the third region 533 relative to the first region 531.

As shown in FIG. 6, the second side surface 54 is connected to the top surface 51 and the bottom surface 52 and faces away from the first side surface 53 in the second direction x. The second side surface 54 includes a fourth region 541, a fifth region 542, and a sixth region 543. The fourth region 541 includes the first direction z as an in-plane direction. As viewed in the first direction z, the fourth region 541 is located outward relative to both the top surface 51 and the bottom surface 52. The fifth region 542 is located between the fourth region 541 and the top surface 51 in the first direction z. The sixth region 543 is located opposite the fifth region 542 with respect to the fourth region 541. Each of the fifth region 542 and the sixth region 543 is inclined relative to the fourth region 541. The inclination angle α2 of the fifth region 542 relative to the fourth region 541 is greater than the inclination angle β2 of the sixth region 543 relative to the fourth region 541.

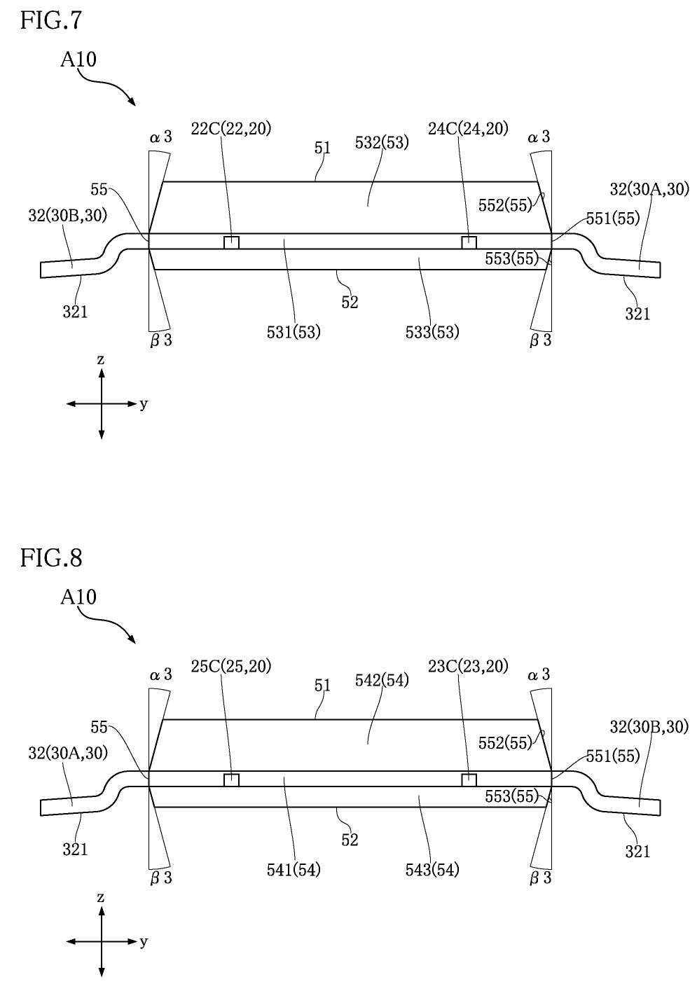

As shown in FIGS. 7 and 8, the two third side surfaces 55 are connected to the top surface 51 and bottom surface 52 and face away from each other in the third direction y. Each of the two third side surfaces 55 includes a seventh region 551, an eighth region 552, and a ninth region 553. The seventh region 551 includes the first direction z as an in-plane direction. As viewed in the first direction z, the seventh region 551 is located outward relative to the top surface 51 and the bottom surface 52. The eighth region 552 is located between the seventh region 551 and the top surface 51 in the first direction z. The ninth region 553 is located opposite the eighth region 552 with respect to the seventh region 551. Each of the eighth region 552 and the ninth region 553 is inclined relative to the seventh region 551. The inclination angle α3 of the eighth region 552 relative to the seventh region 551 is the same as the inclination angle β3 of the ninth region 553 relative to the seventh region 551.

The first lead 20 and the second leads 30 contain copper (Cu). The first lead 20 and the second leads 30 are obtained from the same lead frame.

As shown in FIGS. 3 and 9 to 11, the semiconductor element 10 is mounted on the first lead 20. The first lead 20 has a pad portion 21, a first support part 22, a second support part 23, a third support part 24, and a fourth support part 25.

As shown in FIGS. 3 and 9 to 11, the semiconductor element 10 is mounted on the pad portion 21. As viewed in the first direction z, the first lead 20 is rectangular. The pad portion 21 has a mounting surface 211 and an exposed surface 212. The mounting surface 211 faces one side in the first direction z. The semiconductor element 10 is mounted on the mounting surface 211. The exposed surface 212 faces away from the mounting surface 211 in the first direction z. The exposed surface 212 is exposed from the bottom surface 52 of the sealing resin 50.

As shown in FIGS. 3, 5, and 9, the first support part 22 is connected to the pad portion 21 on one side in the second direction x. The first support part 22 is located closer to the first side surface 53 of the sealing resin 50 than to the second side surface 54 of the sealing resin 50. The first support part 22 has a first surface 22A, a second surface 22B, and a first end surface 22C. The first surface 22A faces the same side as the mounting surface 211 in the first direction z. The second surface 22B faces away from the first surface 22A in the first direction z. The first surface 22A and the second surface 22B are covered with the sealing resin 50. The first end surface 22C faces one side in the second direction x. The first end surface 22C is exposed from the first region 531 of the first side surface 53.

As shown in FIG. 9, the dimension H2 of the sealing resin 50 in the first direction z from the bottom surface 52 of the sealing resin 50 to the second surface 22B is smaller than the dimension H1 of the sealing resin 50 in the first direction z from the top surface 51 of the sealing resin 50 to the first surface 22A. In this case, the dimension H2 is preferably at most 50% of the dimension H1. The dimension L1 of the second surface 22B in the second direction x is at least 50% of a dimension D1. The dimension D1 is the dimension in the second direction x of a region of the bottom surface 52 that is adjacent, on one side in the second direction x, to the exposed surface 212 of the pad portion 21 and overlaps with the second surface 22B as viewed in the first direction z.

As shown in FIGS. 3, 5, and 9, the first support part 22 has a first main portion 221, a first connecting portion 222, and a first end portion 223. The first main portion 221 includes the first surface 22A and the second surface 22B. The first connecting portion 222 is connected to the first main portion 221 and the pad portion 21. The first connecting portion 222 is inclined relative to the mounting surface 211 so as to shift away from the pad portion 21 in the second direction x. The inclination angle γ1 of the first connecting portion 222 relative to the mounting surface 211 is preferably at most 50°. The first end portion 223 is located opposite the first connecting portion 222 with respect to the first main portion 221 in the second direction x and connected to the first main portion 221. The first end portion 223 includes the first surface 22A, the second surface 22B, and the first end surface 22C.

As shown in FIGS. 3, 5, and 12, the first end portion 223 is provided with two first indentations 224 recessed individually from opposite sides in the third direction y. Each of the two first indentations 224 is connected to the edge of the first surface 22A of the first end portion 223 and the edge of the second surface 22B of the first end portion 223. In the semiconductor device A10, because of the provision of the two first indentations 224 at the first end portion 223, the cross-sectional area of the first end portion 223 along a direction orthogonal to the second direction x decreases from the first main portion 221 toward the first end surface 22C.

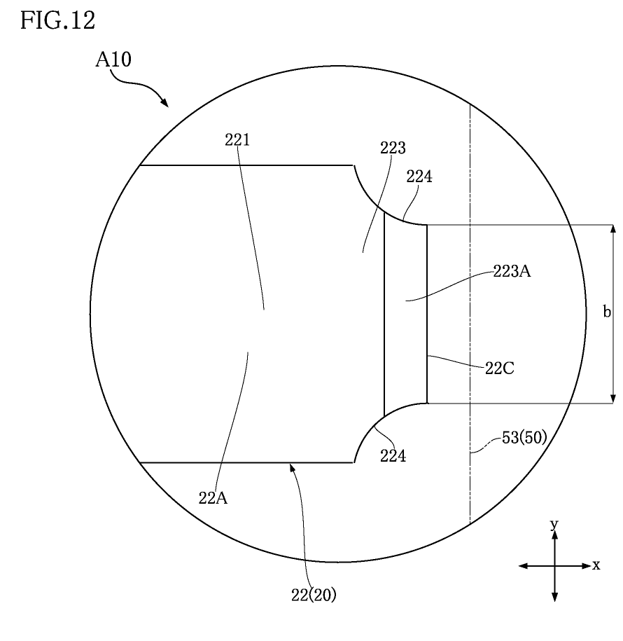

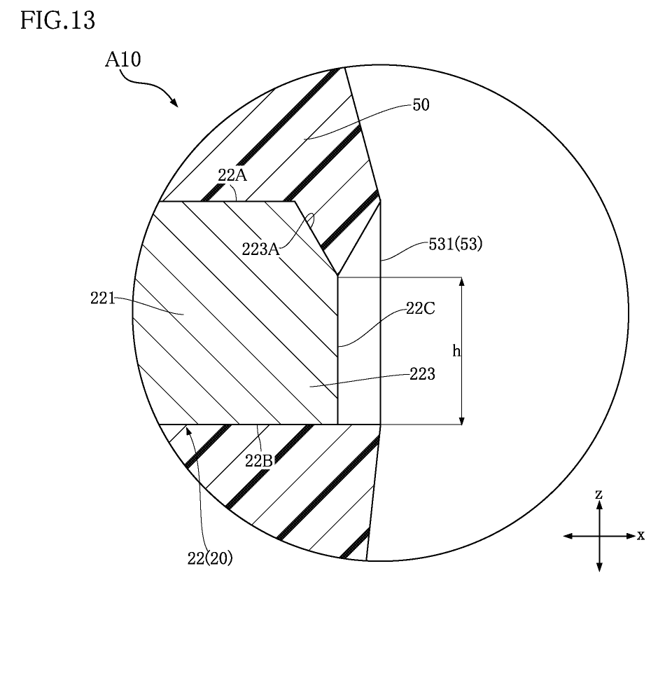

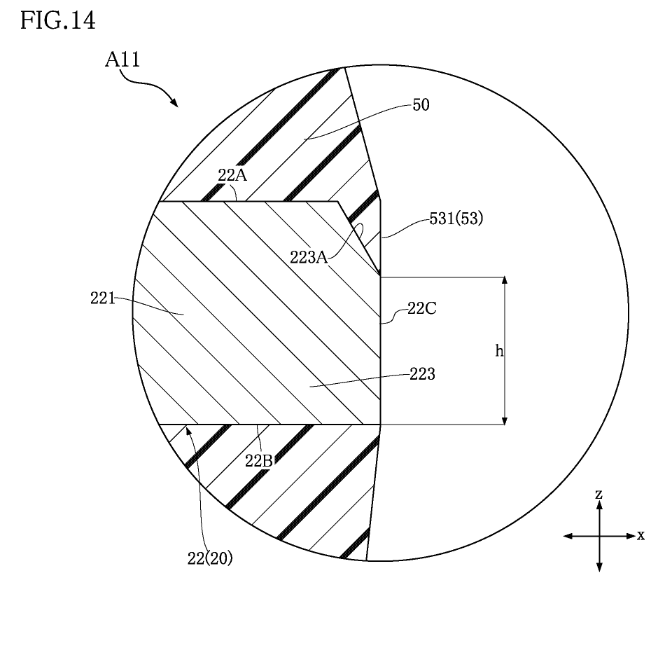

As shown in FIGS. 12 and 13, the first end portion 223 has a first intermediate surface 223A located between the first surface 22A and the first end surface 22C in the second direction x and connected to the first surface 22A. As viewed in the second direction x, the first intermediate surface 223A overlaps with the first main portion 221. The first end surface 22C is located between the first intermediate surface 223A and the second surface 22B in the first direction z. The dimension of the first intermediate surface 223A in the second direction x is smaller than the dimension of the first surface 22A of the first end portion 223 in the second direction x. The first intermediate surface 223A is inclined relative to the first surface 22A toward the inside of the first end portion 223 in the first direction z. The first intermediate surface 223A is connected to the first end surface 22C. The first intermediate surface 223A is covered with the sealing resin 50. The first end surface 22C is spaced apart, in the second direction x, from the first region 531 of the first side surface 53 of the sealing resin 50 toward the side where the pad portion 21 is located.

As shown in FIGS. 12 and 13, the dimension b of the first end surface 22C in the third direction y differs from the dimension h of the first end surface 22C in the first direction z. In the semiconductor device A10, the dimension h is smaller than the dimension b.

As shown in FIGS. 3, 5, and 9, the second support part 23 is located opposite the first support part 22 with respect to the pad portion 21 in the second direction x, and is connected to the pad portion 21. The second support part 23 is located closer to the second side surface 54 of the sealing resin 50 than to the first side surface 53 of the sealing resin 50. The second support part 23 has a third surface 23A, a fourth surface 23B, and a second end surface 23C. The third surface 23A faces the same side as the mounting surface 211 in the first direction z. The fourth surface 23B faces away from the third surface 23A in the first direction z. The third surface 23A and the fourth surface 23B are covered with the sealing resin 50. The second end surface 23C faces away from the first end surface 22C of the first support part 22 in the second direction x. The second end surface 23C is exposed from the fourth region 541 of the second side surface 54.

As shown in FIG. 9, the dimension H4 of the sealing resin 50 in the first direction z from the bottom surface 52 of the sealing resin 50 to the fourth surface 23B is smaller than the dimension H3 of the sealing resin 50 in the first direction z from the top surface 51 of the sealing resin 50 to the third surface 23A. In this case, the dimension H4 is preferably at most 50% of the dimension H3. The dimension L2 of the fourth surface 22B in the second direction x is at least 50% of a dimension D2. The dimension D2 is the dimension in the second direction x of a region of the bottom surface 52 that is adjacent, on one side in the second direction x, to the exposed surface 212 of the pad portion 21 and overlaps with the fourth surface 23B as viewed in the first direction z.

As shown in FIGS. 3, 5, and 9, the second support part 23 has a second main portion 231, a second connecting portion 232, and a second end portion 233. The second main portion 231 includes the third surface 23A and the fourth surface 23B. The second connecting portion 232 is connected to the second main portion 231 and the pad portion 21. The second connecting portion 232 is inclined relative to the mounting surface 211 so as to shift away from the pad portion 21 in the second direction x. The inclination angle γ2 of the second connecting portion 232 relative to the mounting surface 211 is preferably at most 50°. The second end portion 233 is located opposite the second connecting portion 232 with respect to the second main portion 231 in the second direction x and connected to the second main portion 231. The second end portion 233 includes the third surface 23A, the fourth surface 23B, and the second end surface 23C.

As shown in FIGS. 3 and 5, the second end portion 233 is provided with two second indentations 234 recessed individually from opposite sides in the third direction y. Each of the two second indentations 234 is connected to the edge of the third surface 23A of the second end portion 233 and the edge of the fourth surface 23B of the second end portion 233. In the semiconductor device A10, because of the provision of the two second indentations 234 at the second end portion 233, the cross-sectional area of the second end portion 233 along a direction orthogonal to the second direction x decreases from the second main portion 231 toward the second end surface 23C.

The dimension of the pad portion 21 in the second direction x is at least ten times the dimension of each of the first support part 22 and the second support part 23 in the second direction x.

As shown in FIGS. 3, 5, and 10, the third support part 24 is located on the same side as the first support part 22 with respect to the pad portion 21 in the second direction x, and is connected to the pad portion 21. The third support part 24 is spaced apart from the first support part 22 in the third direction y. The third support part 24 has a fifth surface 24A, a sixth surface 24B, and a third end surface 24C. The fifth surface 24A faces the same side as the mounting surface 211 in the first direction z. The sixth surface 24B faces away from the fifth surface 24A in the first direction z. The fifth surface 24A and the sixth surface 24B are covered with the sealing resin 50. The third end surface 24C faces the same side in the second direction x as the first end surface 22C of the first support part 22 . The third end surface 24C is exposed from the first region 531 of the first side surface 53 of the sealing resin 50.

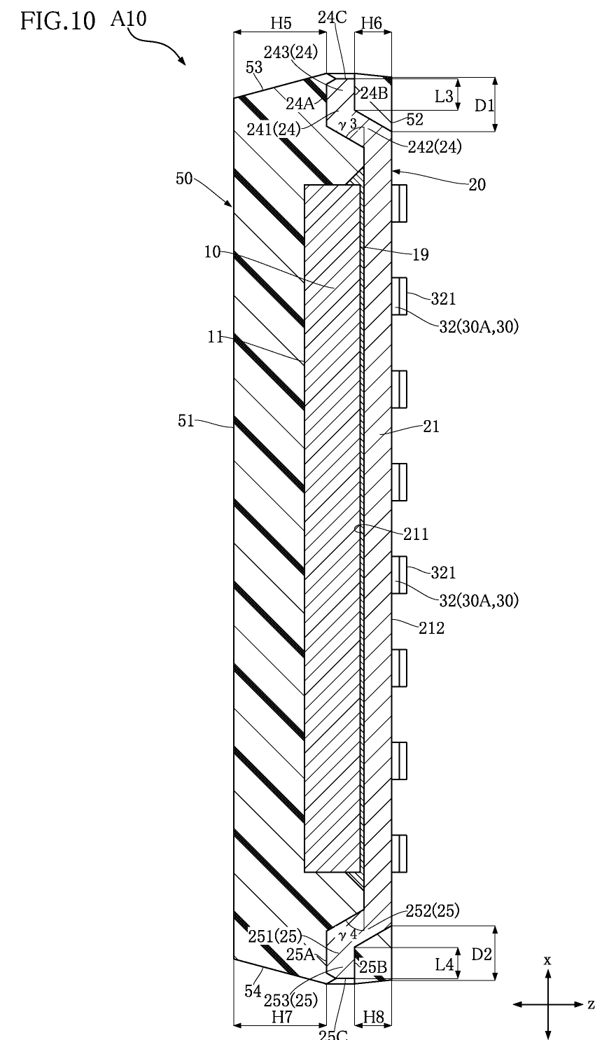

As shown in FIG. 10, the dimension H6 of the sealing resin 50 in the first direction z from the bottom surface 52 of the sealing resin 50 to the sixth surface 24B is smaller than the dimension H5 of the sealing resin 50 in the first direction z from the top surface 51 of the sealing resin 50 to the fifth surface 24A. In this case, the dimension H6 is preferably at most 50% of the dimension H5. The dimension L3 of the sixth surface 24B in the second direction x is at least 50% of a dimension D1. The dimension D1 is the dimension in the second direction x of a region of the bottom surface 52 that is adjacent, on one side in the second direction x, to the exposed surface 212 of the pad portion 21 and overlaps with the sixth surface 24B as viewed in the first direction z.

As shown in FIGS. 3, 5, and 10, the third support part 24 has a third main portion 241, a third connecting portion 242, and a third end portion 243. The third main portion 241 includes the fifth surface 24A and the sixth surface 24B. The third connecting portion 242 is connected to the third main portion 241 and the pad portion 21. The third connecting portion 242 is inclined relative to the mounting surface 211 so as to shift away from the pad portion 21 in the second direction x. The inclination angle γ3 of the third connecting portion 242 relative to the mounting surface 211 is preferably at most 50°. The third end portion 243 is located opposite the third connecting portion 242 with respect to the third main portion 241 in the second direction x and connected to the third main portion 241. The third end portion 243 includes the fifth surface 24A, the sixth surface 24B, and the third end surface 24C.

As shown in FIGS. 3 and 5, the third end portion 243 is provided with two third indentations 244 recessed individually from opposite sides in the third direction y. Each of the two third indentations 244 is connected to the edge of the fifth surface 24A of the third end portion 243 and the edge of the sixth surface 24B of the third end portion 243. In the semiconductor device A10, because of the provision of the two third indentations 244 at the third end portion 243, the cross-sectional area of the third end portion 243 along a direction orthogonal to the second direction x decreases from the third main portion 241 toward the third end surface 24C.

As shown in FIGS. 3, 5, and 10, the fourth support part 25 is located on the same side as the second support part 23 with respect to the pad portion 21 in the second direction x, and is connected to the pad portion 21. The fourth support part 25 is spaced apart from the second support part 23 in the third direction y. The fourth support part 25 has a seventh surface 25A, an eighth surface 25B, and a fourth end surface 25C. The seventh surface 25A faces the same side as the mounting surface 211 in the first direction z. The eighth surface 25B faces away from the seventh surface 25A in the first direction z. The seventh surface 25A and the eighth surface 25B are covered with the sealing resin 50. The fourth end surface 25C faces the same side in the second direction x as the second end surface 23C of the second support part 23. The fourth end surface 25C is exposed from the fourth region 541 of the second side surface 54 of the sealing resin 50.

As shown in FIG. 10, the dimension H8 of the sealing resin 50 in the first direction z from the bottom surface 52 of the sealing resin 50 to the eighth surface 25B is smaller than the dimension H7 of the sealing resin 50 in the first direction z from the top surface 51 of the sealing resin 50 to the seventh surface 25A. In this case, the dimension H8 is preferably at most 50% of the dimension H7. The dimension L4 of the eighth surface 25B in the second direction x is at least 50% of a dimension D2. The dimension D2 is the dimension in the second direction x of a region of the bottom surface 52 that is adjacent, on one side in the second direction x, to the exposed surface 212 of the pad portion 21 and overlaps with the eighth surface 25B as viewed in the first direction z.

As shown in FIGS. 3, 5, and 10, the fourth support part 25 has a fourth main portion 251, a fourth connecting portion 252, and a fourth end portion 253. The fourth main portion 251 includes a seventh surface 25A and an eighth surface 25B. The fourth connecting portion 252 is connected to the fourth main portion 251 and the pad portion 21. The fourth connecting portion 252 is inclined relative to the mounting surface 211 so as to shift away from the pad portion 21 in the second direction x. The inclination angle γ4 of the fourth connecting portion 252 relative to the mounting surface 211 is preferably at most 50°. The fourth end portion 253 is located opposite the fourth connecting portion 252 with respect to the fourth main portion 251 in the second direction x and connected to the fourth main portion 251. The fourth end portion 253 includes the seventh surface 25A, the eighth surface 25B, and the fourth end surface 25C.

As shown in FIGS. 3 and 5, the fourth end portion 253 is provided with two fourth indentations 254 recessed individually from opposite sides in the third direction y. Each of the two fourth indentations 254 is connected to the edge of the seventh surface 25A of the fourth end portion 253 and the edge of the eighth surface 25B of the fourth end portion 253. In the semiconductor device A10, because of the provision of the two fourth indentations 254 at the fourth end portion 253, the cross-sectional area of the fourth end portion 253 along a direction orthogonal to the second direction x decreases from the fourth main portion 251 toward the fourth end surface 25C.

The semiconductor element 10 is mounted on the pad portion 21 of the first lead 20, as shown in FIGS. 3 and 9 to 11. The semiconductor element 10 performs the functions of the semiconductor device A10. The type of the semiconductor element 10 is not limited and may be an IC or an LSI, for example. The semiconductor element 10 is bonded to the mounting surface 211 of the pad portion 21 via the bonding layer 19. The bonding layer 19 is made of a paste containing metal particles. These metal particles are, for example, silver (Ag). Therefore, the bonding layer 19 is a conductor. Alternatively, the bonding layer 19 may be solder.

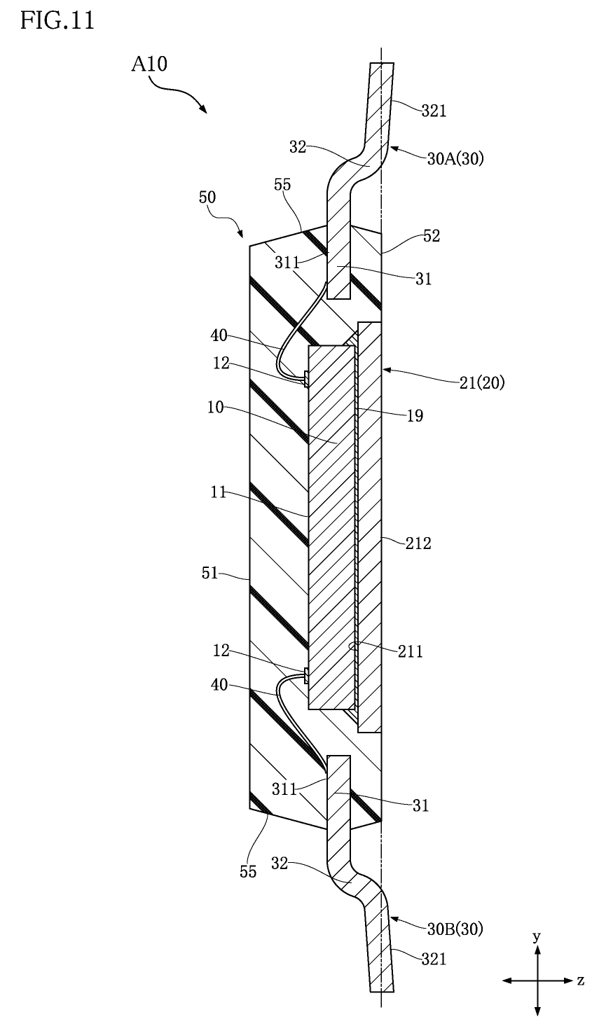

As shown in FIGS. 3 and 11, the semiconductor element 10 has an element surface 11 and a plurality of electrodes 12. The element surface 11 faces the same side as the mounting surface 211 of the pad portion 21 in the first direction z. In the first direction z, the element surface 11 is located between the top surface 51 of the sealing resin 50 and each of the first surface 22A of the first support part 22, the third surface 23A of the second support part 23, the fifth surface 24A of the third support part 24, and the seventh surface 25A of the fourth support part 25. Thus, as viewed in a direction orthogonal to the first direction z, the semiconductor element 10 includes a portion protruding in the first direction z from each of the first support part 22, the second support part 23, the third support part 24, and the fourth support part 25. The electrodes 12 are provided on the element surface 11. Each of the electrodes 12 is electrically connected to a circuit formed in the semiconductor element 10.

As shown in FIGS. 3 and 5, the second leads 30 are disposed on both sides in the third direction y of the first lead 20. Each of the second leads 30 is electrically connected to the semiconductor element 10. The second leads 30 include a plurality of first terminals 30A and a plurality of second terminals 30B. The first terminals 30A are located on one side of the first lead 20 in the third direction y. The first terminals 30A are arranged along the second direction x. Each of the first terminals 30A protrudes from the seventh region 551 of one of the two third side surfaces 55 of the sealing resin 50. The second terminals 30B are located opposite the first terminals 30A with respect to the first lead 20 in the third direction y. The second terminals 30B are arranged along the second direction x. Each of the second terminals 30B protrudes from the seventh region 551 of the other one of the two third side surfaces 55.

As shown in FIGS. 3 and 5, each of the second leads 30 has an inner portion 31 and an outer portion 32. The inner portion 31 is covered with the sealing resin 50. As shown in FIGS. 3 and 11, the inner portion 31 of each of the second leads 30 has a connecting surface 311. The connecting surface 311 faces the same side as the mounting surface 211 of the pad portion 21 in the first direction z. The connecting surface 311 is located between the mounting surface 211 and the top surface 51 of the sealing resin 50 in the first direction z. In the semiconductor device A10, the connecting surface 311 is located between the mounting surface 211 and the element surface 11 of the semiconductor element 10 in the first direction z. Furthermore, in the semiconductor device A10, the connecting surface 311 of each of the second leads 30, the first surface 22A of the first support part 22, the third surface 23A of the second support part 23, the fifth surface 24A of the third support part 24, and the seventh surface 25A of the fourth support part 25 are all contained within the same plane.

As shown in FIGS. 3 and 5, each outer portion 32 is connected to the inner portion 31 of a corresponding one of the second leads 30. The outer portion 32 protrudes from the seventh region 551 of one of the two third side surfaces 55 of the sealing resin 50. The surface of the outer portion 32 may be provided with, for example, tin plating. As viewed in the first direction z, the outer portion 32 extends in the third direction y. As viewed in the second direction x, the outer portion 32 is bent in a gull-wing shape.

As shown in FIGS. 5 and 11, the outer portion 32 of each of second leads 30 has an attachment surface 321. The attachment surface 321 is exposed from the sealing resin 50. In the first direction z, the attachment surface 321 faces away from the connecting surface 311 of the corresponding inner portion 31 and is located farthest from the connecting surface 311 of the corresponding inner portion 31. The attachment surface 321 protrudes from the plane containing the bottom surface 52 of the sealing resin 50. The attachment surface 321 is inclined relative to the bottom surface 52.

The wires 40 are individually conductively bonded to the electrodes 12 of the semiconductor element 10 and the connecting surfaces 311 of the second leads 30, as shown in FIGS. 3 and 11. Thus, each of the second leads 30 is electrically connected to the semiconductor element 10. The wires 40 include, for example, gold (Au). Alternatively, the wires 40 may include aluminum (Al) or copper.

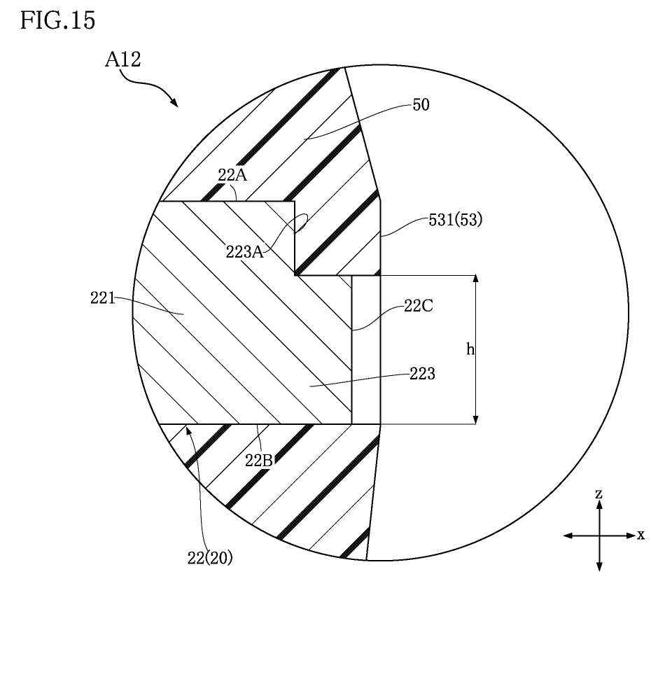

Next, with reference to FIG. 14, a semiconductor device A11 according to a first variation of the first embodiment of the present disclosure will be described. FIG. 14 corresponds to FIG. 13 that shows the semiconductor device A10. In the semiconductor device A11, the configuration of the first support part 22 of the first lead 20 differs from that of the semiconductor device A10.

As shown in FIG. 14, the first end surface 22C of the first support part 22 is flush with the first region 531 of the first side surface 53 of the sealing resin 50.

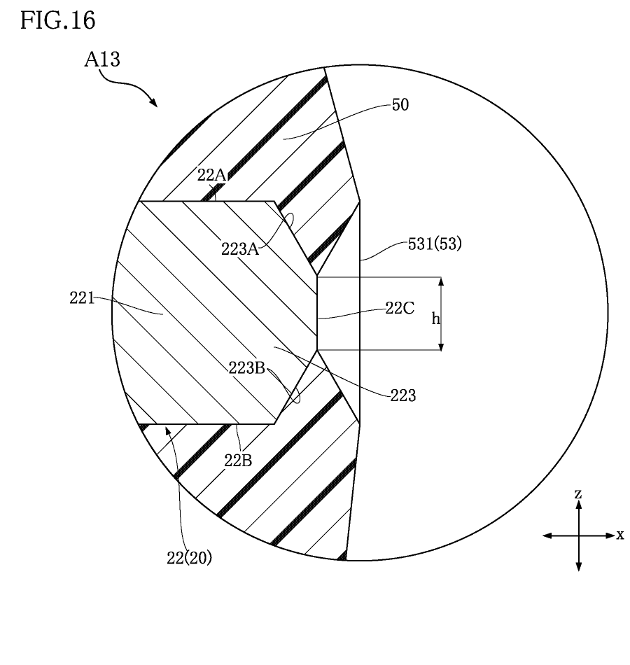

Next, with reference to FIG. 15, a semiconductor device A12 according to a second variation of the first embodiment of the present disclosure will be described. FIG. 15 corresponds to FIG. 13 that shows the semiconductor device A10. In the semiconductor device A12, the configuration of the first support part 22 of the first lead 20 differs from that of the semiconductor device A10.

As shown in FIG. 15, the in-plane directions of the first intermediate surface 223A of the first end portion 223 of the first support part 22 include the first direction z. The first intermediate surface 223A is spaced apart from the first end surface 22C of the first support part 22.

Next, with reference to FIG. 16, a semiconductor device A13 according to a third variation of the first embodiment of the present disclosure will be described. FIG. 16 corresponds to FIG. 13 that shows the semiconductor device A10. In the semiconductor device A13, the configuration of the first support part 22 of the first lead 20 differs from that of the semiconductor device A10.

As shown in FIG. 16, the first end portion 223 has a second intermediate surface 223B located between the second surface 22B and the first end surface 22C in the second direction x and connected to the second surface 22B. As viewed in the second direction x, the second intermediate surface 223B overlaps with the first main portion 221. The first end surface 22C is located between the first intermediate surface 223A and the second intermediate surface 223B in the first direction z. The dimension of the second intermediate surface 223B in the second direction x is smaller than the dimension of the second surface 22B of the first end portion 223 in the second direction x. The second intermediate surface 223B is inclined relative to the second surface 22B toward the inside of the first end portion 223 in the first direction z and connected to the first end surface 22C. The second intermediate surface 223B is covered with the sealing resin 50.

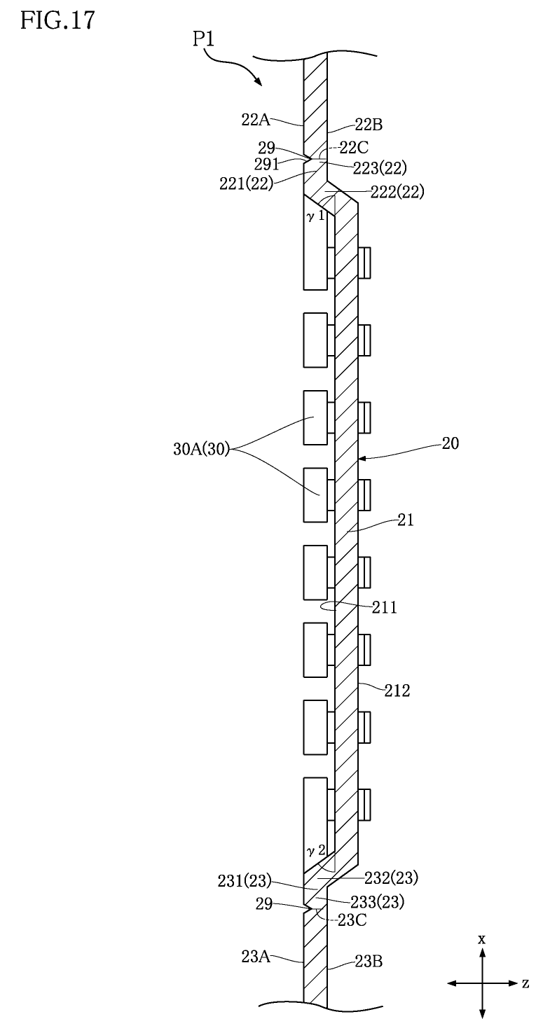

Next, with reference to FIGS. 17 to 20, an example of a method for manufacturing the semiconductor device A10 will be described. FIGS. 17 to 20 correspond to FIG. 9, which shows the semiconductor device A10.

First, as shown in FIG. 17, a first process P1 is performed to form a first lead 20 having a pad portion 21, a first support part 22, and a second support part 23. The first process P1 is performed during the formation of a lead frame including the first lead 20 and a plurality of second leads 30. In the description of the manufacturing method for the semiconductor device A10, the description of the formation of the third support part 24 and the fourth support part 25 of the first lead 20 is omitted. In the first process P1, two first indentations 224 are formed at the first end portion 223 of the first support part 22 to cause the cross-sectional area of the first end portion 223 along a direction orthogonal to the second direction x to decrease from the first main portion 221 of the first support part 22 toward the first end surface 22C. Also, two second indentations 234 are formed at the second end portion 233 of the second support part 23 to cause the cross-sectional area of the second end portion 233 along a direction orthogonal to the second direction x to decrease from the second main portion 231 of the second support part 23 toward the second end surface 23C.

As shown in FIG. 17, in the first process P1, a groove 29 recessed from the first surface 22A of the first support part 22 and a groove 29 recessed from the third surface 23A of the second support part 23 are formed in the first support part 22 and the second support part 23, respectively. The grooves 29 extend in the third direction y. The grooves 29 are defined by the inner surfaces 291 connected to either the first surface 22A or the third surface 23A. In the second direction x, the groove 29 formed in the first support part 22 is located opposite the first main portion 221 with respect to the two first indentations 224. In the second direction x, the groove 29 formed in the second support part 23 is located opposite the second main portion 231 with respect to the two second indentations 234.

Furthermore, as shown in FIG. 17, in the first process P1, the first connecting portion 222 of the first support part 22 is inclined relative to the mounting surface 211 so as to shift away from the pad portion 21 in the second direction x. Also, the second connecting portion 232 of the second support part 23 is inclined relative to the mounting surface 211 so as to shift away from the pad portion 21 in the second direction x. The respective inclination angles γ1 and γ2 of the first connecting portion 222 and the second connecting portion 232 relative to the mounting surface 211 are preferably at most 50°.

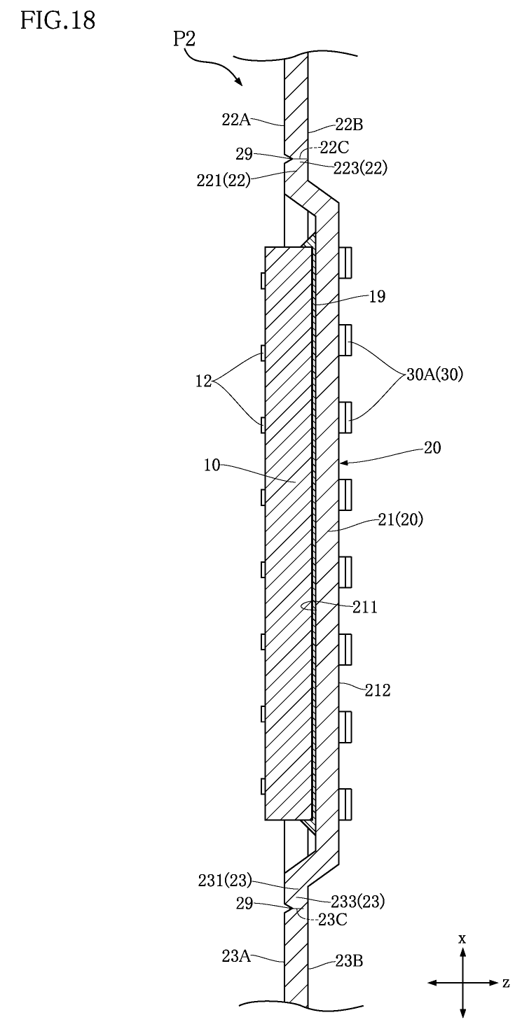

Next, as shown in FIG. 18, a second process P2 is performed to bond the semiconductor element 10 to the mounting surface 211 of the pad portion 21. In the second process P2, the semiconductor element 10 is bonded to the mounting surface 211 via the bonding layer 19. Subsequently, although not shown, wire bonding is performed to conductively bond the wires 40 individually to the electrodes 12 of the semiconductor element 10 and the connecting surfaces 311 of the second leads 30.

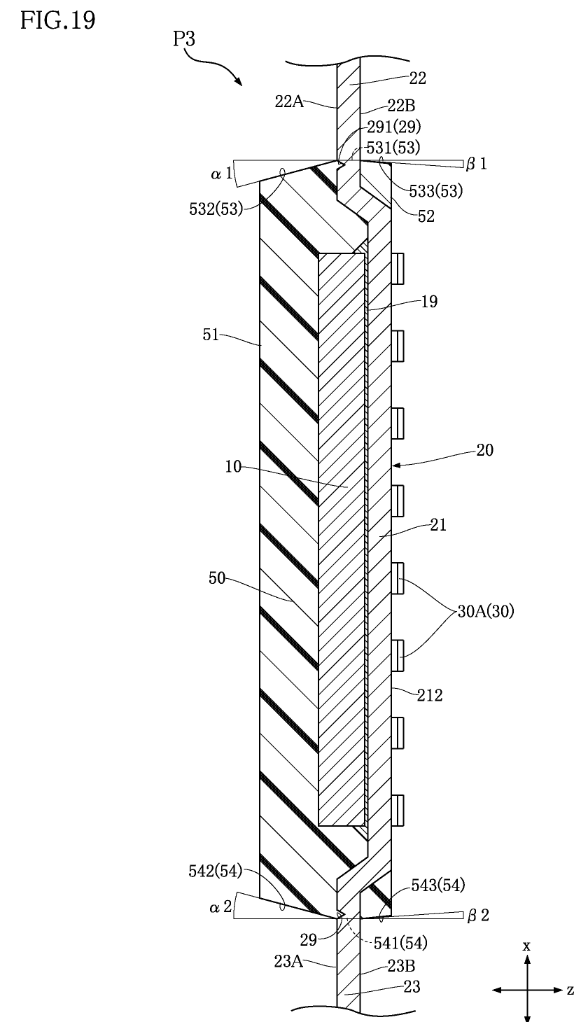

Next, as shown in FIG. 19, a third process P3 is performed to form the sealing resin 50 covering a portion of the pad portion 21, a portion of the first support part 22, a portion of the second support part 23, and the semiconductor element 10. The sealing resin 50 is formed by transfer molding. In the third process P3, a portion of each of the first surface 22A and the second surface 22B of the first support part 22 and a portion of each of the third surface 23A and the fourth surface 23B of the second support part 23 are covered with the sealing resin 50. Additionally, the exposed surface 212 of the pad portion 21 is exposed from the bottom surface 52. The dimension H2 shown in FIG. 9 is made smaller than the dimension H1. The dimension H4 shown in FIG. 9 is made smaller than the dimension H3.

As shown in FIG. 19, in the third process P3, the first support part 22 is caused to protrude from the first region 531 of the first side surface 53 of the sealing resin 50. At this time, the inclination angle α1 of the second region 532 of the first side surface 53 relative to the first region 531 is made larger than the inclination angle β1 of the third region 533 of the first side surface 53 relative to the first region 531. Also, the second support part 23 is caused to protrude from the fourth region 541 of the second side surface 54 of the sealing resin 50. At this time, the inclination angle α2 of the fifth region 542 of the second side surface 54 relative to the fourth region 541 is made larger than the inclination angle β2 of the sixth region 543 of the second side surface 54 relative to the fourth region 541.

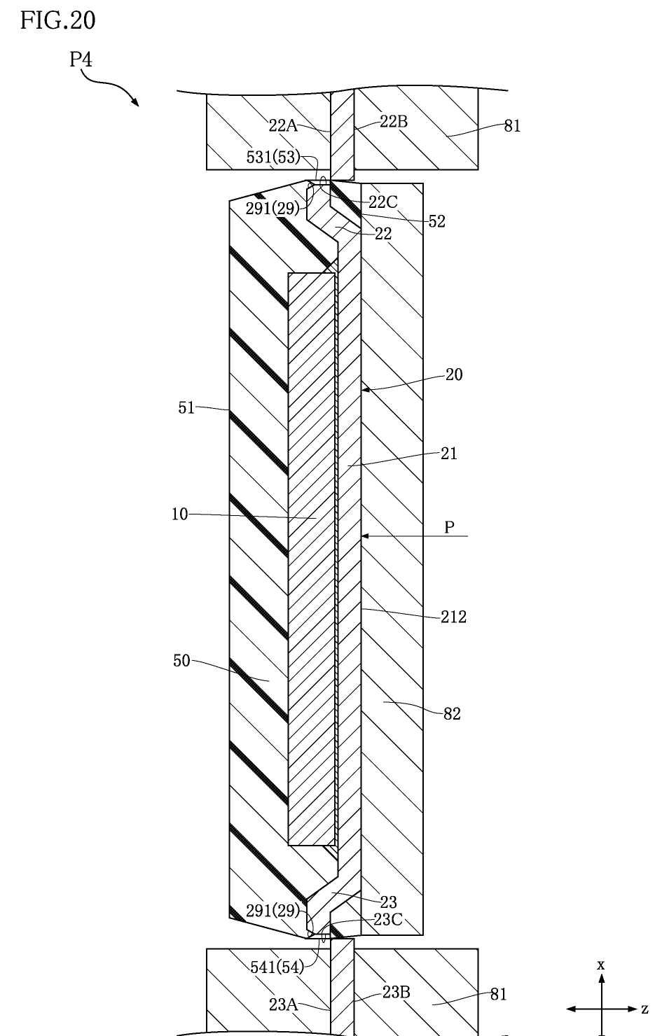

Next, as shown in FIG. 20, a fourth process P4 is performed to cut the first support part 22 and the second support part 23. In the fourth process P4, the first surface 22A and the second surface 22B of the first support part 22 and the third surface 23A and the fourth surface 23B of the second support part 23 are supported on the support member 81. Subsequently, a loading body 82 is used to apply a compressive force P to the exposed surface 212 of the pad portion 21 and the bottom surface 52 of the sealing resin 50, thereby cutting the first support part 22 and the second support part 23. In the fourth process P4, a first end surface 22C, which corresponds to the cut surface of the first support part 22, is formed at the first end portion 223. Also, a second end surface 23C, which corresponds to the cut surface of the second support part 23, is formed at the second end portion 233. Each of the first support part 22 and the second support part 23 is cut starting from the groove 29. In the first support part 22, a portion of the inner surface 291 defining the groove 29 corresponds to the first intermediate surface 223A of the first end portion 223. By performing the above steps, the semiconductor device A10 is obtained.

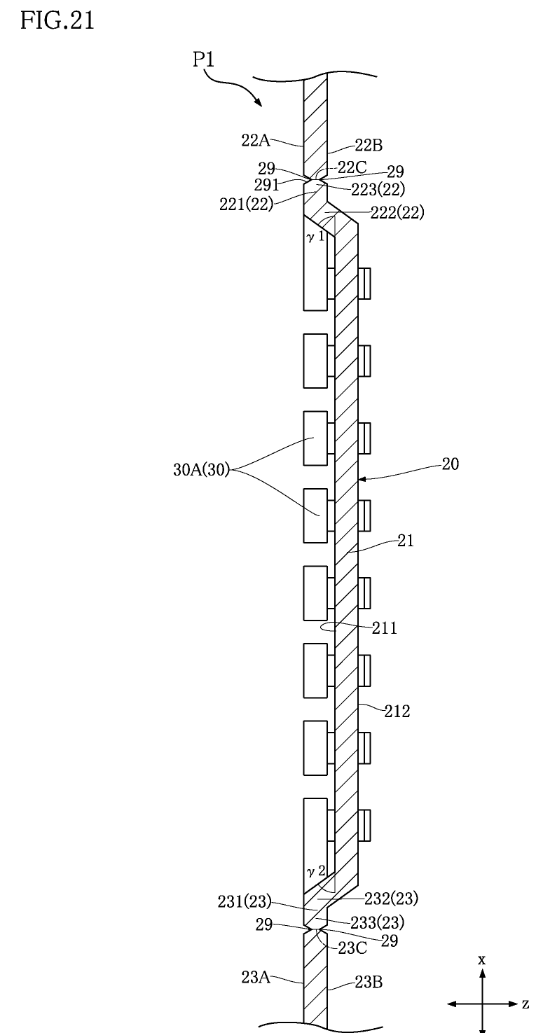

Next, with reference to FIG. 21, an example of a method for manufacturing the semiconductor device A13 will be described. FIG. 21 corresponds to FIG. 9, which shows the semiconductor device A10.

As shown in FIG. 21, in the first process P1 related to the manufacture of the semiconductor device A13, a groove 29 recessed from the first surface 22A and a groove 29 recessed the second surface 22B are formed in the first support part 22, while a groove 29 recessed from the third surface 23A and a groove 29 recessed the fourth surface 23B are formed in the the second support part 23. In this process, the groove 29 in the second surface 22B of the first support part 22 and the groove 29 in the first surface 22A of the first support part 22 are formed so as to overlap with each other as viewed in the first direction z. Similarly, the groove 29 in the fourth surface 23B of the second support part 23 and the groove 29 in the third surface 23A of the second support part 23 are formed so as to overlap with each other as viewed in the first direction z. The second process P2, the third process P3, and the fourth process P4 related to the manufacture of the semiconductor device A13 are the same as in the case of the manufacture of the semiconductor device A10, so that the description here is omitted.

Next, the effects of the semiconductor device A10 will be described.

The semiconductor device A10 includes a first lead 20 having a pad portion 21 and a first support part 22, a semiconductor element 10, and a sealing resin 50. The first support part 22 has a first surface 22A, a second surface 22B, and a first end surface 22C. The pad portion 21 is exposed from the bottom surface 52 of the sealing resin 50. The dimension H2 of the sealing resin 50 in the first direction z from the bottom surface 52 to the second surface 22B is smaller than the dimension H1 of the sealing resin 50 in the first direction z from the top surface 51 to the first surface 22A. The dimension L1 of the second surface 22B in the second direction x is at least 50% of the dimension D1, where the dimension D1 is the dimension in the second direction x of a region of the bottom surface 52 that is adjacent, on one side in the second direction x, to the pad portion 21 and overlaps with the second surface 22B as viewed in the first direction z. With such a configuration, the concentration of compressive stress, which acts on the sealing resin 50 from the first support part 22 upon cutting the first support part 22, is reduced in the fourth process P4 shown in FIG. 20. Thus, with the semiconductor device A10 having the present configuration, it is possible to reduce the concentration of the stress in the sealing resin 50 that acts upon cutting the first lead 20 during the manufacturing of the semiconductor device A10.

The cross-sectional area of the first end portion 223 of the first support part 22 along a direction orthogonal to the second direction x decreases from the first main portion 221 toward the first end surface 22C. This configuration reduces the area of the first end surface 22C, thereby facilitating the cutting of the first support part 22 in the fourth process P4 shown in FIG. 20.

The first end portion 223 of the first support part 22 has a first intermediate surface 223A. As viewed in the second direction x, the first intermediate surface 223A overlaps with the first main portion 221. The first end surface 22C of the first support part 22 is located between the first intermediate surface 223A and the second surface 22B in the first direction z. This configuration allows the dimension h of the first end surface 22C of the first support part 22 in the first direction z to be smaller than the dimension b of the first end surface 22C in the third direction y. This reduces the second moment of area about the third direction y of the first end surface 22C, thereby facilitating cutting of the first support part 22 in the fourth process P4 shown in FIG. 20.

The first connecting portion 222 of the first support part 22 is inclined relative to the mounting surface 211 so as to shift away from the pad portion 21 in the second direction x. With such a configuration, the concentration of compressive stress, which acts on the sealing resin 50 from the first support part 22 upon cutting the first support part 22, is further reduced in the fourth process P4 shown in FIG. 20. Thus, it is possible to further reduce the concentration of the stress in the sealing resin 50 that acts upon cutting the first lead 20.

In the sealing resin 50, the inclination angle α1 of the second region 532 of the first side surface 53 relative to the first region 531 of the first side surface 53 is greater than the inclination angle β1 of the third region 533 of the first side surface 53 relative to the first region 531. With such a configuration, when the dimension H1 shown in FIG. 9 is larger than the dimension H2, it is possible to suppress the defects in the sealing resin 50 caused by the withdrawal of the molding die in the third process P3 shown in FIG. 19.

### Second Embodiment:

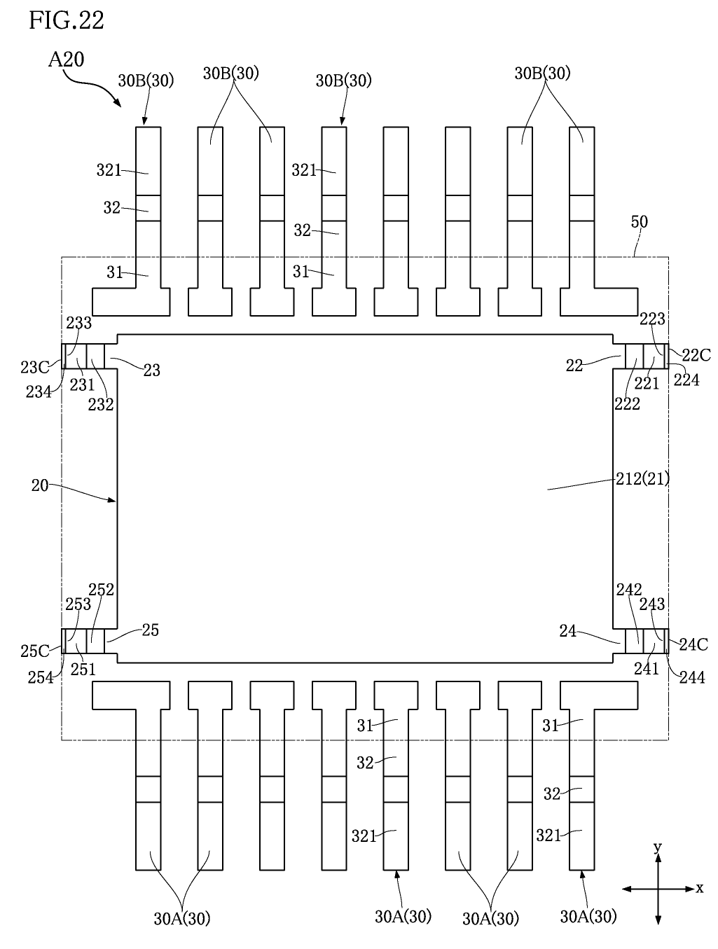

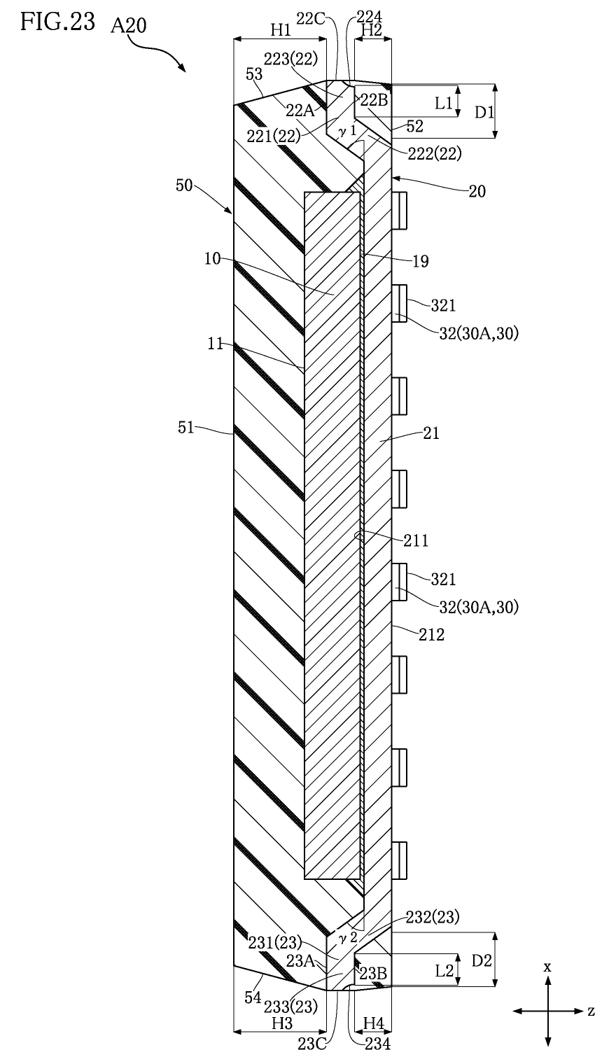

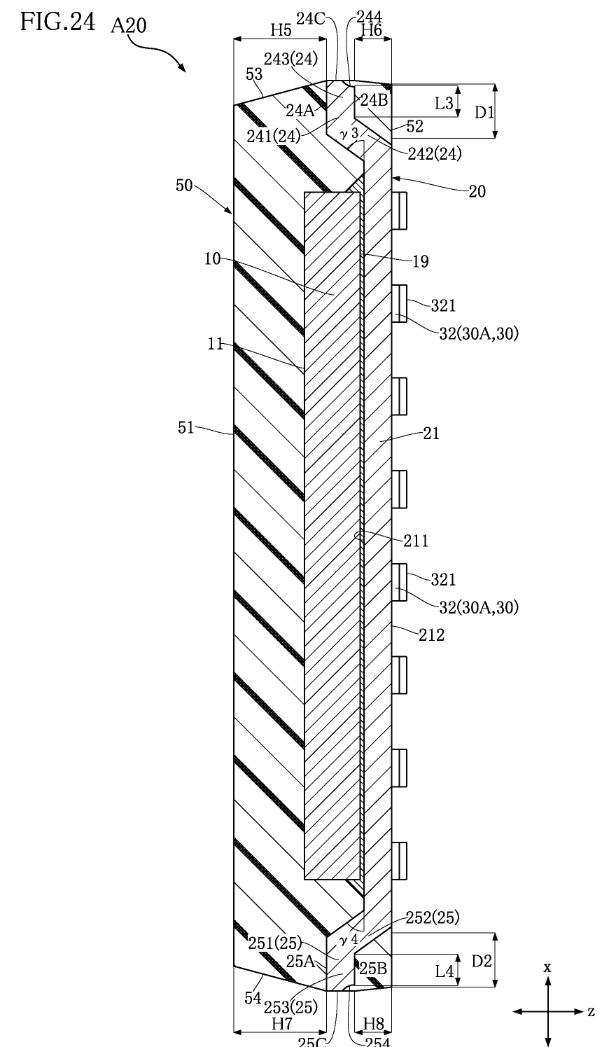

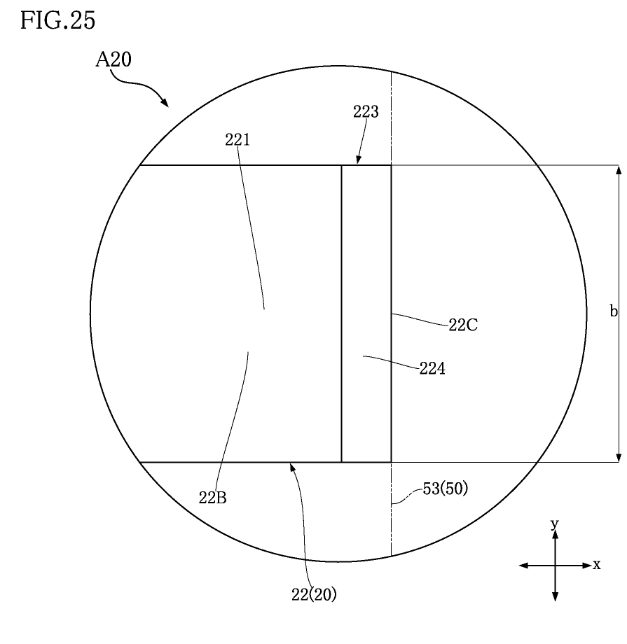

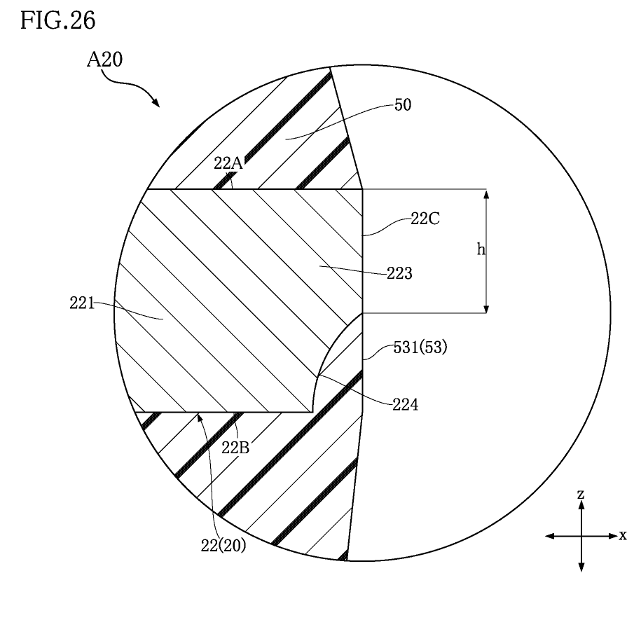

A semiconductor device A20 according to a second embodiment of the present disclosure will be described with reference to FIGS. 22 to 26. In these figures, the elements that are identical or similar to those of the semiconductor device A10 described above are denoted by the same reference numerals, and the descriptions are omitted. FIG. 22 shows the sealing resin 50 as transparent for ease of understanding. In FIG. 22, the outline of the sealing resin 50 is indicated by an imaginary line. FIG. 23 corresponds to FIG. 9, which shows the semiconductor device A10. FIG. 24 corresponds to FIG. 10, which shows the semiconductor device A10.

In the semiconductor device A20, the configuration of the first support part 22, the second support part 23, the third support part 24, and the fourth support part 25 of the first lead 20 differs from the corresponding configuration in the semiconductor device A10.

As shown in FIGS. 22 and 23, the first end portion 223 of the first support part 22 has a first indentation 224 recessed from the second surface 22B. The first indentation 224 is connected to the first main portion 221 and the first end surface 22C. The second end portion 233 of the second support part 23 has a second indentation 234 recessed from the fourth surface 23B. The second indentation 234 is connected to the second main portion 231 and the second end surface 23C.

As shown in FIGS. 22 and 24, the third end portion 243 of the third support part 24 has a third indentation 244 recessed from the sixth surface 24B. The third indentation 244 is connected to the third main portion 241 and the third end surface 24C. The fourth end portion 253 of the fourth support part 25 has a fourth indentation 254 recessed from the eighth surface 25B. The fourth indentation 254 is connected to the fourth main portion 251 and the fourth end surface 25C.

As shown in FIG. 26, in the first support part 22, the first indentation 224 of the first end portion 223 is in contact with the sealing resin 50. The dimension of the first indentation 224 in the second direction x is smaller than the dimension L1 of the second surface 22B of the first support part 22. The first end surface 22C is flush with the first region 531 of the first side surface 53 of the sealing resin 50.

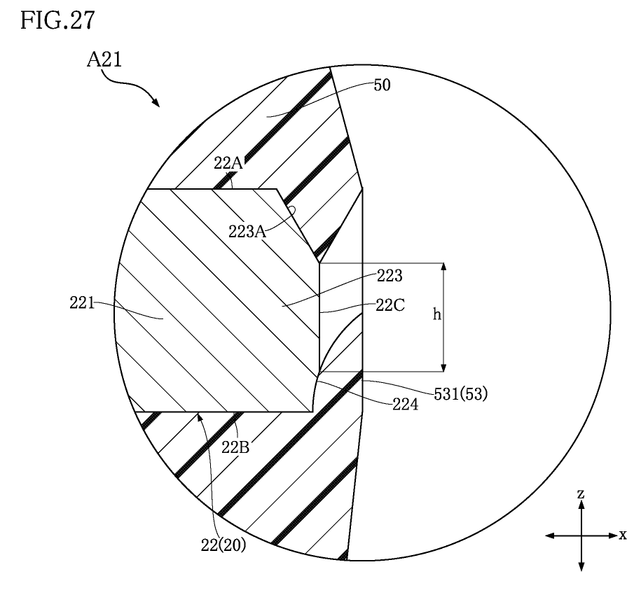

Next, a semiconductor device A21 according to a variation of the second embodiment of the present disclosure will be described with reference to FIG. 27. FIG. 27 corresponds to FIG. 26, which shows the semiconductor device A20. In the semiconductor device A21, the configuration of the first support part 22 of the first lead 20 differs from that of the semiconductor device A20.

As shown in FIG. 27, the first end portion 223 has a first intermediate surface 223A located between the first surface 22A and the first end surface 22C in the second direction x and connected to the first surface 22A. As viewed in the second direction x, the first intermediate surface 223A overlaps with the first main portion 221. The first end surface 22C is located between the first intermediate surface 223A and the second indentation 234 in the first direction z. The dimension of the first intermediate surface 223A in the second direction x is larger than the dimension of the second indentation 234 in the second direction x. The first intermediate surface 223A is inclined relative to the first surface 22A toward the inside of the first end portion 223 in the first direction z and connected to the first end surface 22C. The first intermediate surface 223A is covered with the sealing resin 50.

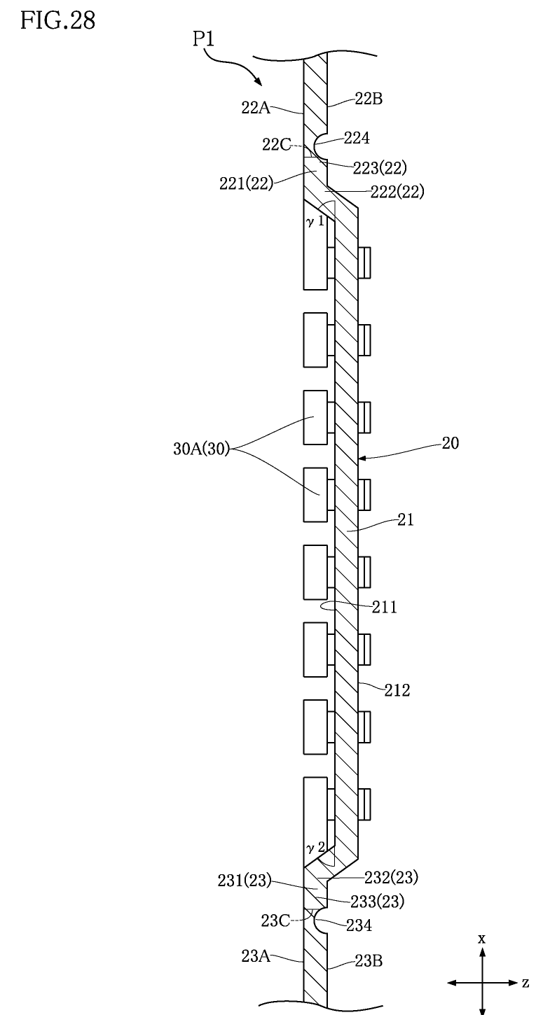

Next, with reference to FIGS. 28 to 30, an example of a method for manufacturing the semiconductor device A20 will be described. FIGS. 28 to 30 correspond to FIG. 23, which shows the semiconductor device A20.

First, as shown in FIG. 28, a first process P1 is performed to form a first lead 20 having a pad portion 21, a first support part 22, and a second support part 23. In the first process P1, a first indentation 224 is formed at the first end portion 223 of the first support part 22 to cause the cross-sectional area of the first end portion 223 along a direction orthogonal to the second direction x to decrease from the first main portion 221 of the first support part 22 toward the first end surface 22C. Also, a second indentation 234 is formed at the second end portion 233 of the second support part 23 to cause the cross-sectional area of the second end portion 233 along a direction orthogonal to the second direction x to decrease from the second main portion 231 of the second support part 23 toward the second end surface 23C.

Next, a second process P2 is performed to bond the semiconductor element 10 to the mounting surface 211 of the pad portion 21. Since the second process P2 is the same as the second process P2 related to the manufacture of the semiconductor device A10 shown in FIG. 18, the description here is omitted.

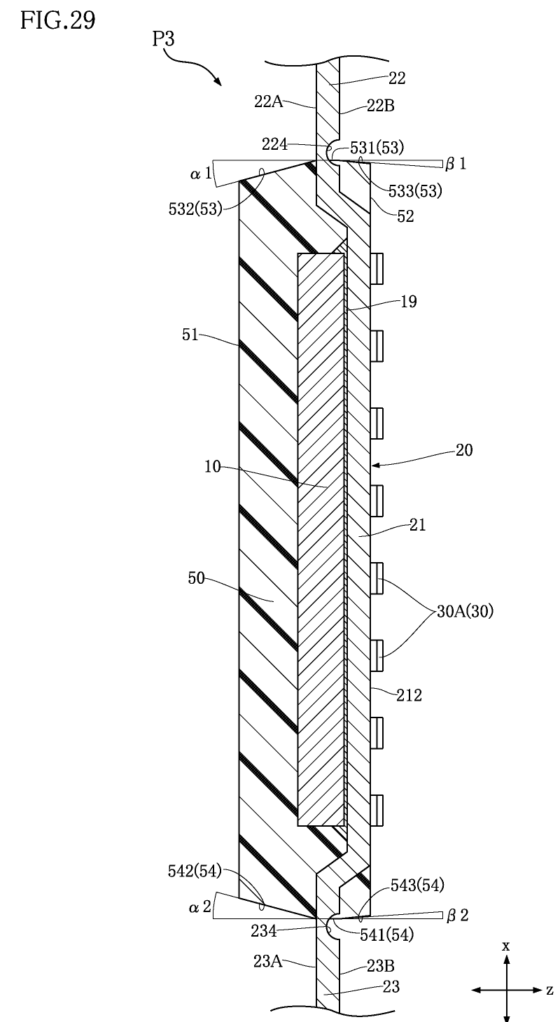

Next, as shown in FIG. 29, a third process P3 is performed to form the sealing resin 50 covering a portion of the pad portion 21, a portion of the first support part 22, a portion of the second support part 23, and the semiconductor element 10. In the third process P3, at least a portion of the first indentation 224 formed at the first support part 22 and at least a portion of the second indentation 234 formed at the second support part 23 are covered with the sealing resin 50.

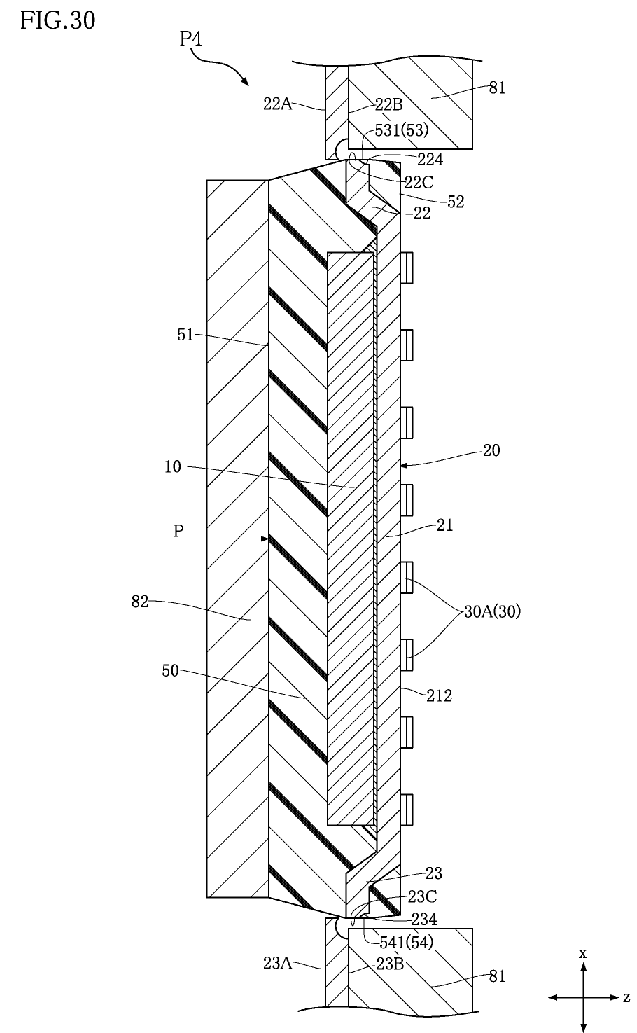

Next, as shown in FIG. 30, a fourth process P4 is performed to cut the first support part 22 and the second support part 23. In the fourth process P4, the second surface 22B of the first support part 22 and the fourth surface 23B of the second support part 23 are supported on the support member 81. Subsequently, a loading body 82 is used to apply a compressive force P to the top surface 51 of the sealing resin 50, thereby cutting the first support part 22 and the second support part 23. The first support part 22 is cut starting from the first indentation 224. The second support part 23 is cut starting from the second indentation 234. By performing the above steps, the semiconductor device A20 is obtained.

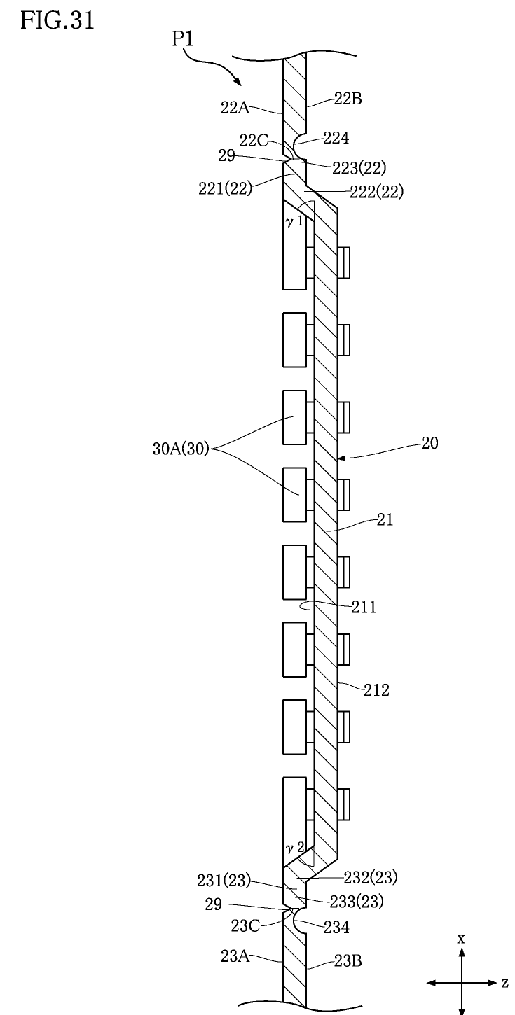

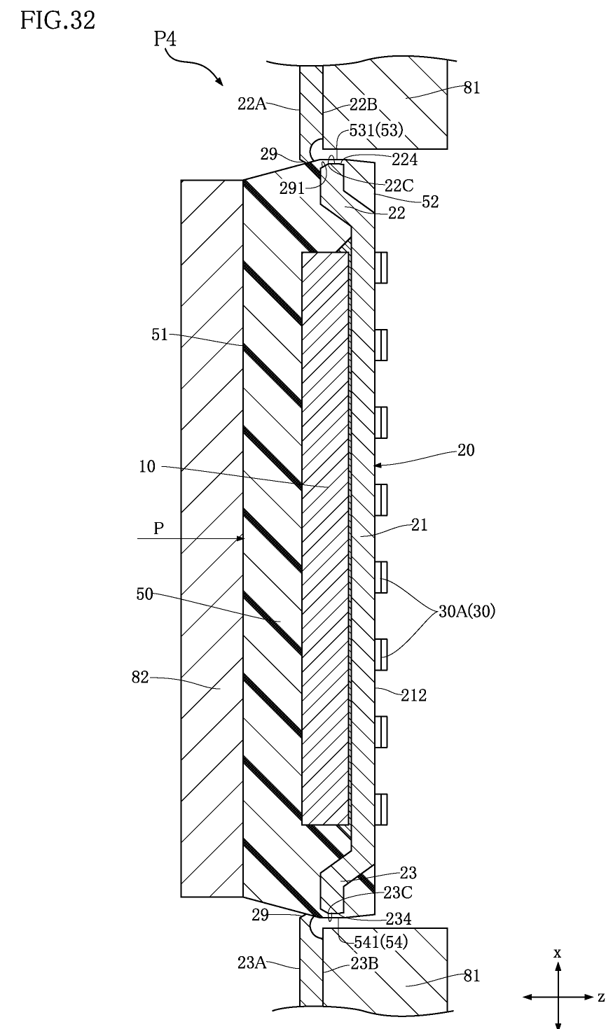

Next, with reference to FIGS. 31 and 32, an example of a method for manufacturing the semiconductor device A21 will be described. FIGS. 31 to 32 correspond to FIG. 23, which shows the semiconductor device A20.

As shown in FIG. 31, in the first process P1 related to the manufacture of the semiconductor device A21, a groove 29 recessed from the first surface 22A of the first support part 22 and a groove 29 recessed from the third surface 23A of the second support part 23 are formed in the first support part 22 and the second support part 23, respectively. The groove 29 in the first support part 22 is formed so as to overlap with the first indentation 224 as viewed in the first direction z. Similarly, the groove 29 in the second support part 23 is formed so as to overlap with the second indentation 234 as viewed in the first direction z. The second process P2 and third process P3 related to the manufacture of semiconductor device A21 are the same as in the case of the manufacture of the semiconductor device A20, so that the description here is omitted.

As shown in FIG. 32, in the fourth process P4 related to the manufacture of the semiconductor device A21, the first support part 22 is cut starting from both the first indentation 224 and the groove 29. The second support part 23 is cut starting from both the second indentation 234 and the groove 29. In the first support part 22, a portion of the inner surface 291 defining the groove 29 corresponds to the first intermediate surface 223A of the first end portion 223.

Next, the effects of the semiconductor device A20 will be described.

The semiconductor device A20 includes a first lead 20 having a pad portion 21 and a first support part 22, a semiconductor element 10, and a sealing resin 50. The first support part 22 has a first surface 22A, a second surface 22B, and a first end surface 22C. The pad portion 21 is exposed from the bottom surface 52 of the sealing resin 50. The dimension H2 of the sealing resin 50 in the first direction z from bottom surface 52 to the second surface 22B is smaller than the dimension H1 of the sealing resin 50 in the first direction z from the top surface 51 to the first surface 22A. The dimension L1 of the second surface 22B in the second direction x is at least 50% of the dimension D1, where the dimension D1 is the dimension in the second direction x of a region of the bottom surface 52 that is adjacent, on one side in the second direction x, to the pad portion 21 and overlaps with the second surface 22B as viewed in the first direction z. With such a configuration, the semiconductor device A20 can also reduce the stress concentration in the sealing resin 50 that acts upon cutting of the first lead 20 during the manufacture of the semiconductor device A20. Furthermore, the semiconductor device A20 has a configuration in common with the semiconductor device A10, thereby achieving the same effect as the semiconductor device A10.

In the semiconductor device A20, the first end portion 223 of the first support part 22 has a first indentation 224 recessed from the second surface 22B. The first indentation 224 is connected to the first main portion 221. With such a configuration, during the fourth process P4 shown in FIG. 30, the first support part 22 is cut starting from the first indentation 224 while a compressive force P acts on the top surface 51 of the sealing resin 50. This facilitates smoother cutting of the first support part 22. Furthermore, the dimension h of the first end surface 22C of the first support part 22 in the first direction z can be made further smaller than the dimension b of the first end surface 22C in the third direction y. This further reduces the the second moment of area about the third direction y of the first end surface 22C.

The present disclosure is not limited to the embodiments described above. Various modifications in design may be made freely in the specific structure of each part of the the present disclosure.

The present disclosure includes the embodiments described in the following clauses.

Clause 1. A semiconductor device comprising: a first lead including a pad portion and a first support part, the pad portion including a mounting surface facing one side in a first direction, the first support part being connected to the pad portion on one side in a second direction orthogonal to the first direction; a semiconductor element bonded to the mounting surface; and a sealing resin covering a portion of the first lead while also covering the semiconductor element, wherein the sealing resin includes a top surface facing a same side as the mounting surface in the first direction and a bottom surface facing away from the top surface in the first direction, the pad portion being exposed from the bottom surface, the first support part includes a first surface facing the same side as the top surface in the first direction and covered with the sealing resin, a second surface facing away from the first surface in the first direction and covered with the sealing resin, and a first end surface facing one side in the second direction and exposed from the sealing resin, a dimension of the sealing resin in the first direction from the bottom surface to the second surface is smaller than a dimension of the sealing resin in the first direction from the top surface to the first surface, and a dimension of the second surface in the second direction is at least 50% of a dimension in the second direction of a region of the bottom surface, the region being adjacent, on one side in the second direction, to the pad portion and overlapping with the second surface as viewed in the first direction.

Clause 2. The semiconductor device according to clause 1, wherein the first support part includes a first main portion including the first surface and the second surface, a first connecting portion connected to the first main portion and the pad portion, and a first end portion located opposite the first connecting portion with respect to the first main portion in the second direction and connected to the first main portion, the first end portion includes the first surface and the first end surface, and a cross-sectional area of the first end portion along a direction orthogonal to the second direction decreases from the first main portion toward the first end surface.

Clause 3. The semiconductor device according to clause 2, wherein a dimension of the first end surface in a third direction orthogonal to each of the first direction and the second direction is different from a dimension of the first end surface in the first direction.

Clause 4. The semiconductor device according to clause 3, wherein the first end portion includes an indentation recessed from one side in the third direction, and the indentation is connected to an edge of the first surface of of the first end portion.

Clause 5. The semiconductor device according to clause 4, wherein the first end portion includes a first intermediate surface located between the first surface and the first end surface in the second direction and connected to the first surface, as viewed in the second direction, the first intermediate surface overlaps with the first main portion, and the first end surface is located between the first intermediate surface and the second surface in the first direction.

Clause 6. The semiconductor device according to clause 5, wherein a dimension of the first intermediate surface in the second direction is smaller than a dimension of the first surface of the first end portion in the second direction.

Clause 7. The semiconductor device according to clause 6, wherein the first intermediate surface is inclined relative to the first surface toward an inside of the first end portion in the first direction.

Clause 8. The semiconductor device according to clause 6, wherein the dimension of the first end surface in the first direction is smaller than a dimension of the first end surface in the third direction.

Clause 9. The semiconductor device according to clause 3, wherein the first end portion includes an indentation recessed from the second surface, and the indentation is connected to the first main portion.

Clause 10. The semiconductor device according to any one of clauses 3 to 9, wherein the first connecting portion is inclined relative to the mounting surface so as to shift away from the pad portion in the second direction.

Clause 11. The semiconductor device according to clause 10, wherein the first lead includes a second support part located opposite the first support part with respect to the pad portion in the second direction and connected to the pad portion, the second support part includes a third surface facing the same side as the top surface in the first direction and covered with the sealing resin, a fourth surface facing away from the third surface in the first direction and covered with the sealing resin, and a second end surface facing away from the first end surface in the second direction and exposed from the sealing resin, a dimension of the sealing resin in the first direction from the bottom surface to the fourth surface is smaller than a dimension of the sealing resin in the first direction from the top surface to the third surface, and a dimension of the fourth surface in the second direction is at least 50% of a dimension in the second direction of a region of the bottom surface, the region being adjacent, on one side in the second direction, to the pad portion and overlapping with the fourth surface as viewed in the first direction.

Clause 12. The semiconductor device according to clause 11, wherein the second support part includes a second main portion including the third surface and the fourth surface, a second connecting portion connected to the second main portion and the pad portion, and a second end portion located opposite the second connecting portion with respect to the second main portion in the second direction and connected to the second main portion, the second end portion includes the third surface and the second end surface, and a cross-sectional area of the second end portion along a direction orthogonal to the second direction decreases from the second main portion toward the second end surface.

Clause 13. The semiconductor device according to clause 12, wherein the first lead includes a third support part located on a same side as the first support part with respect to the pad portion in the second direction and connected to the pad portion, the third support part is spaced apart from the first support part in the third direction, the third support part includes a third end surface facing a same side as the first end surface in the second direction and exposed from the sealing resin, and a cross-sectional area of the third support part along a direction orthogonal to the second direction decreases from a side where the pad portion is located toward the third end surface.

Clause 14. The semiconductor device according to clause 12, wherein the sealing resin includes a first side surface and a second side surface facing away from each other in the second direction, the first side surface includes a first region including the first direction as an in-plane direction thereof, a second region located between the first region and the top surface in the first direction, and a third region located opposite the second region with respect to the first region, each of the second region and the third region is inclined relative to the first region, the first end surface is exposed from the first region, and the second end surface is exposed from the second side surface.

Clause 15. The semiconductor device according to clause 14, wherein an inclination angle of the second region relative to the first region is greater than an inclination angle of the third region relative to the first region.

Clause 16. The semiconductor device according to clause 15, wherein the first end surface is spaced apart, in the second direction, from the first region toward a side where the pad portion is located.

Clause 17. The semiconductor device according to clause 14, further comprising a second lead electrically connected to the semiconductor element, wherein the sealing resin includes a third side surface facing one side in the second direction, and the second lead protrudes from the third side surface.

Clause 18. The semiconductor device according to clause 17, further comprising a wire conductively bonded to the semiconductor element and the second lead, wherein the second lead includes a connecting surface facing the same side as the mounting surface in the first direction and covered with the sealing resin, the connecting surface is located between the top surface and the mounting surface in the first direction, and the wire is conductively bonded to the connecting surface.

Clause 19. The semiconductor device according to clause 18, wherein the semiconductor element includes an element surface facing the same side as the mounting surface in the first direction, and the element surface is located between the top surface and the first and the third surfaces in the first direction.

Clause 20. The semiconductor device according to clause 19, wherein the connecting surface is located between the element surface and the mounting surface in the first direction.

Clause 21. The semiconductor device according to any one of clauses 5 to 8, wherein the second end portion includes a second surface, and the indentation is connected to an edge of the second surface of the second end portion.

Clause 22. The semiconductor device according to clause 21, wherein the indentation includes a first portion and a second portion spaced apart from each other in the third direction, and the first portion and the second portion are recessed individually from opposite sides in the third direction of the first end portion.

Clause 23. The semiconductor device according to clause 21, wherein the first end portion includes a second intermediate surface located between the second surface and the first end surface in the second direction and connected to the second surface, as viewed in the second direction, the second intermediate surface overlaps with the first main portion, and the first end portion is located between the first intermediate surface and the second intermediate surface in the first direction.

Clause 24. The semiconductor device according to clause 23, wherein a dimension of the second intermediate surface in the second direction is smaller than a dimension of the second surface of the first end portion in the second direction.

Clause 25. The semiconductor device according to clause 24, wherein the second intermediate surface is inclined relative to the second surface toward an inside of the first end portion in the first direction.

Clause 26. The semiconductor device according to clause 18, wherein the second lead includes an attachment surface exposed from the sealing resin and facing away from the connecting surface in the first direction, the attachment surface is located farthest from the connecting surface in the first direction, and the attachment surface protrudes from a plane containing the bottom surface.

Clause 27. The semiconductor device according to clause 27, wherein the attachment surface is inclined relative to the bottom surface.

Clause 28. The semiconductor device according to clause 10, wherein a dimension of the pad portion in the second direction is at least ten times a dimension of the first support part in the second direction.

### REFERENCE NUMERALS

A10, A20: Semiconductor device 10: Semiconductor element 11: Element surface 12: Electrode 19: Bonding layer 20: First lead 21: Pad portion 211: Mounting surface 212: Exposed surface 22: First support part 22A: First surface 22B: Second surface 22C: First end surface 221: First main portion 222: First connecting portion 223: First end portion 223A: First intermediate surface 223B: Second intermediate surface 224: First indentation 23: Second support part 23A: Third surface 23B: Fourth surface 23C: Second end surface 231: Second main portion 232: Second connecting portion 233: Second end portion 234: Second indentation 24: Third support part 24A: Fifth surface 24B: Sixth surface 24C: Third end surface 241: Third main portion 242: Third connecting portion 243: Third end portion 244:Third indentation 25:Fourth support part 25A:Seventh surface 25B: Eighth surface 25C: Fourth end surface 251: Fourth main portion 252: Fourth connecting portion 253: Fourth end portion 254: Fourth indentation 29: Groove 291: Inner surface 30: Second lead 30A: First terminal 30B: Second terminal 31: Inner portion 311: Connecting surface 32: Outer portion 321: Attachment surface 40: Wire 50: Sealing resin 51: Top surface 52: bottom surface 53: First side surface 531 to 533: First region to third region 54: Second side surface 541 to 543: Fourth region to sixth region 55: Third side surface 551 to 553: Seventh region to ninth region P1 to P4: First process to fourth process z: first direction x: Second direction y: Third direction

1. A semiconductor device comprising:
a first lead including a pad portion and a first support part, the pad portion including a mounting surface facing one side in a first direction, the first support part being connected to the pad portion on one side in a second direction orthogonal to the first direction;
a semiconductor element bonded to the mounting surface; and
a sealing resin covering a portion of the first lead while also covering the semiconductor element, wherein
the sealing resin includes a top surface facing a same side as the mounting surface in the first direction and a bottom surface facing away from the top surface in the first direction, the pad portion being exposed from the bottom surface,
the first support part includes a first surface facing the same side as the top surface in the first direction and covered with the sealing resin, a second surface facing away from the first surface in the first direction and covered with the sealing resin, and a first end surface facing one side in the second direction and exposed from the sealing resin,
a dimension of the sealing resin in the first direction from the bottom surface to the second surface is smaller than a dimension of the sealing resin in the first direction from the top surface to the first surface, and
a dimension of the second surface in the second direction is at least 50% of a dimension in the second direction of a region of the bottom surface, the region being adjacent, on one side in the second direction, to the pad portion and overlapping with the second surface as viewed in the first direction.

2. The semiconductor device according to claim 1, wherein the first support part includes a first main portion including the first surface and the second surface, a first connecting portion connected to the first main portion and the pad portion, and a first end portion located opposite the first connecting portion with respect to the first main portion in the second direction and connected to the first main portion,
the first end portion includes the first surface and the first end surface, and
a cross-sectional area of the first end portion along a direction orthogonal to the second direction decreases from the first main portion toward the first end surface.

3. The semiconductor device according to claim 2, wherein a dimension of the first end surface in a third direction orthogonal to each of the first direction and the second direction is different from a dimension of the first end surface in the first direction.

4. The semiconductor device according to claim 3, wherein the first end portion includes an indentation recessed from one side in the third direction, and
the indentation is connected to an edge of the first surface of of the first end portion.

5. The semiconductor device according to claim 4, wherein the first end portion includes an intermediate surface located between the first surface and the first end surface in the second direction and connected to the first surface,
as viewed in the second direction, the intermediate surface overlaps with the first main portion, and
the first end surface is located between the intermediate surface and the second surface in the first direction.

6. The semiconductor device according to claim 5, wherein a dimension of the intermediate surface in the second direction is smaller than a dimension of the first surface of the first end portion in the second direction.

7. The semiconductor device according to claim 6, wherein the intermediate surface is inclined relative to the first surface toward an inside of the first end portion in the first direction.

8. The semiconductor device according to claim 6, wherein the dimension of the first end surface in the first direction is smaller than a dimension of the first end surface in the third direction.

9. The semiconductor device according to claim 3, wherein the first end portion includes an indentation recessed from the second surface, and
the indentation is connected to the first main portion.

10. The semiconductor device according to claim 3, wherein the first connecting portion is inclined relative to the mounting surface so as to shift away from the pad portion in the second direction.

11. The semiconductor device according to claim 10, wherein the first lead includes a second support part located opposite the first support part with respect to the pad portion in the second direction and connected to the pad portion,
the second support part includes a third surface facing the same side as the top surface in the first direction and covered with the sealing resin, a fourth surface facing away from the third surface in the first direction and covered with the sealing resin, and a second end surface facing away from the first end surface in the second direction and exposed from the sealing resin,
a dimension of the sealing resin in the first direction from the bottom surface to the fourth surface is smaller than a dimension of the sealing resin in the first direction from the top surface to the third surface, and
a dimension of the fourth surface in the second direction is at least 50% of a dimension in the second direction of a region of the bottom surface, the region being adjacent, on one side in the second direction, to the pad portion and overlapping with the fourth surface as viewed in the first direction.

12. The semiconductor device according to claim 11, wherein the second support part includes a second main portion including the third surface and the fourth surface, a second connecting portion connected to the second main portion and the pad portion, and a second end portion located opposite the second connecting portion with respect to the second main portion in the second direction and connected to the second main portion,
the second end portion includes the third surface and the second end surface, and
a cross-sectional area of the second end portion along a direction orthogonal to the second direction decreases from the second main portion toward the second end surface.

13. The semiconductor device according to claim 12, wherein the first lead includes a third support part located on a same side as the first support part with respect to the pad portion in the second direction and connected to the pad portion,
the third support part is spaced apart from the first support part in the third direction,
the third support part includes a third end surface facing a same side as the first end surface in the second direction and exposed from the sealing resin, and
a cross-sectional area of the third support part along a direction orthogonal to the second direction decreases from a side where the pad portion is located toward the third end surface.

14. The semiconductor device according to claim 12, wherein the sealing resin includes a first side surface and a second side surface facing away from each other in the second direction,
the first side surface includes a first region including the first direction as an in-plane direction thereof, a second region located between the first region and the top surface in the first direction, and a third region located opposite the second region with respect to the first region,
each of the second region and the third region is inclined relative to the first region,
the first end surface is exposed from the first region, and
the second end surface is exposed from the second side surface.

15. The semiconductor device according to claim 14, wherein an inclination angle of the second region relative to the first region is greater than an inclination angle of the third region relative to the first region.

16. The semiconductor device according to claim 15, wherein the first end surface is spaced apart, in the second direction, from the first region toward a side where the pad portion is located.

17. The semiconductor device according to claim 14, further comprising a second lead electrically connected to the semiconductor element, wherein
the sealing resin includes a third side surface facing one side in the third direction, and
the second lead protrudes from the third side surface.

18. The semiconductor device according to claim 17, further comprising a wire conductively bonded to the semiconductor element and the second lead, wherein
the second lead includes a connecting surface facing the same side as the mounting surface in the first direction and covered with the sealing resin,
the connecting surface is located between the top surface and the mounting surface in the first direction, and
the wire is conductively bonded to the connecting surface.

19. The semiconductor device according to claim 18, wherein the semiconductor element includes an element surface facing the same side as the mounting surface in the first direction, and
the element surface is located between the top surface and the first and the third surfaces in the first direction.

20. The semiconductor device according to claim 19, wherein the connecting surface is located between the element surface and the mounting surface in the first direction.
